(19) United States
(12) Patent Application Publication
(10) Pub. No.: US 2017/0210958 A1
(43) Pub. Date: Jul. 27, 2017

(54) CMP POLISHING LIQUID, AND POLISHING METHOD

(71) Applicant: HITACHI CHEMICAL COMPANY, LTD., Tokyo (JP)

(72) Inventors: Takashi SHINODA, Tokyo (JP); Munehiro OOTA, Tokyo (JP); Nao YAMAMURA, Tokyo (JP); Aiko KINO, Tokyo (JP)

(21) Appl. No.: 15/324,146

(22) PCT Filed: Jul. 3, 2015
(86) PCT No.: PCT/JP2015/069297

§ 371 Date: Jan. 5, 2017

(30) Foreign Application Priority Data
Jul. 9, 2014 (JP) 2014-141670
Jul. 9, 2014 (JP) 2014-141673

(51) Int. Cl. C09K 3/14; H01L 21/3105; C09G 1/02; B24B 37/11; B24B 57/02

(52) U.S. Cl. CPC C09K 3/1409; B24B 37/11; B24B 57/02; C09G 1/02; H01L 21/31053

(57) ABSTRACT

A CMP polishing liquid for polishing an insulating material, comprising a cerium oxide particle satisfying the conditions (A) and (B) below, a 4-pyrone-based compound, and water:
condition (A): an average particle diameter R of the cerium oxide particle is 50 nm or more and 300 nm or less, and
condition (B): when the cerium oxide particle is defined as a spherical particle having the average particle diameter R, sphericity S2/S1 provided by a specific surface area S1 of the spherical particle and a specific surface area S2 of the cerium oxide particle measured by the BET method is 3.15 or less.

### TECHNICAL FIELD

The present invention relates to a CMP polishing liquid and a polishing method. Particularly, the present invention relates to a CMP polishing liquid used for chemical mechanical polishing (CMP) in the production process of semiconductor devices, and a polishing method using the CMP polishing liquid.

### BACKGROUND ART

In the field of semiconductor production, with achievement of high performance of semiconductor devices, a miniaturization technology as an extension of the conventional technology finds restriction in allowing high integration and speed-up to be compatible with each other. Accordingly, while miniaturization of semiconductor elements is being promoted, techniques for multilayered wiring have been developed as techniques for allowing vertical high integration.

In the process for producing a semiconductor device comprising multilayered wiring, one of the most important techniques is a CMP technique. The CMP technique is a technique of flattening the surface of a thin film formed on a substrate by, for example, chemical vapor deposition (CVD). For example, a treatment based on CMP is indispensable for securing the depth of focus in lithography.

The CMP technique is applied, in a production process of a semiconductor device, for example, to a shallow trench isolation (STI) formation step of forming an element isolation region by polishing an insulating material such as BPSG, HDP-SiO₂ and p-TEOS, an ILD formation step of forming an interlayer insulating material (ILD), a plug formation step of flattening a plug (an Al plug, a Cu plug and the like) after an insulating material is embedded in a metal wiring, or a damascene step of forming an embedded wiring of a metal.

In the STI formation step, an insulating material is formed so as to fill a groove beforehand formed on the substrate surface, and then, the surface of the insulating material is flattened by CMP using a CMP polishing liquid.

Also, in the ILD formation step, since the groove to be formed is generally deep, the insulating material is formed thicker as compared with the STI formation step. Then, the surface of the insulating material is similarly flattened by CMP using a CMP polishing liquid.

As the polishing liquid used in the STI formation step or the ILD formation step, various polishing liquids for polishing insulating materials are known. Such polishing liquids are classified into silica-based polishing liquids, ceria (cerium oxide)-based polishing liquids, alumina-based polishing liquids, and the like, depending on the types of abrasive grains comprised in the polishing liquids.

As the ceria-based polishing liquids, Patent Literature 1 below describes a polishing liquid for semiconductor using a highly pure cerium oxide abrasive grain. Patent Literature 2 below describes a polishing liquid comprising a ceria particle having at least two crystallites and having a crystal grain boundary. Patent Literature 3 below describes a technique of adding a polymer additive in order to control the polishing rate of a ceria-based polishing liquid and to enhance global flatness.

All of the ceria-based polishing liquids employ a fired ceria particle obtained by firing a cerium compound as an abrasive grain. On the other hand, in recent years, a polishing liquid using a colloidal ceria particle has also been known, as in the polishing liquids of Patent Literatures 4 and 5 below.

### CITATION LIST

### Patent Literature

Patent Literature 1: Japanese Unexamined Patent Publication No. H10-106994

Patent Literature 2: International Publication No. WO 99/31195

Patent Literature 3: Japanese Patent No. 3278532

Patent Literature 4: International Publication No. WO 2008/043703

Patent Literature 5: International Publication No. WO 2010/036358

### SUMMARY OF INVENTION

### Technical Problem

When an insulating material is formed on a substrate in the STI formation step, the ILD formation step, or the like, irregularities also occur on the surface of the insulating material in accordance with the irregular shape of the substrate surface before the formation of the insulating material. If the concave regions are slowly removed while the convex regions are preferentially removed for the surface having such irregularities, the surface can be efficiently flattened.

In the case where STI is adopted in order to respond to the achievement of the narrow width of the element isolation region, it is required for the CMP polishing liquid used in the CMP step that, for example, the unnecessary portion (particularly, convex regions) of the insulating material formed on the substrate should be removed at a polishing rate as high as possible. In addition to this, it is required that the surface after the completion of polishing should be finished as flat surface. These requirements must also be satisfied for the ILD formation step.

In other words, a CMP polishing liquid that efficiently exerts both of the characteristics described above is a polishing liquid having a high polishing rate of the convex regions and a large polishing rate ratio between the convex regions and the concave regions (ratio of the polishing rate of the convex regions with respect to the polishing rate of the concave regions) in the polishing of the insulating material having irregularities on the surface thereof (i.e., a polishing liquid excellent in step height elimination characteristics). In the case where the polishing rate ratio between the convex regions and the concave regions is large, it is considered that the convex regions are selectively polished, and as the irregularities of the surface to be polished are reduced in size, the polishing rate is slowed down and the finished surface is more flat.

Herein, the polishing rate ratio between the convex regions and the concave regions in the polishing of the insulating material having irregularities on the surface thereof tends to be increased as the ratio of the polishing rate of the convex regions of the insulating material having irregularities with respect to the polishing rate of an insulating material having no irregularities is increased. Therefore, for obtaining the large polishing rate ratio between the convex regions and the concave regions, it is necessary to enhance the ratio of the polishing rate of the convex regions of the insulating material having irregularities with respect to the polishing rate of an insulating material having no irregularities. For example, it is necessary to enhance the polishing rate of the convex regions of a patterned wafer with respect to the polishing rate of a blanket wafer.

However, it is not easy to enhance the step height elimination characteristics. Particularly, with miniaturization in the design rule of semiconductor devices in recent years, highly precise processing is necessary, and it is required to further flatten the irregularities of the surface. Against this technical background, further enhancement in step height elimination characteristics is desired.

The present invention is directed to solve the above problems, and an object thereof is to provide a CMP polishing liquid capable of obtaining excellent step height elimination characteristics for an insulating material having irregularities. Another object of the present invention is to provide a polishing method using the CMP polishing liquid.

### Solution to Problem

The present inventors made a diligent study on the abrasive grain and the additives to be comprised in the CMP polishing liquid in order to solve the above problems. The present inventors prepared a large number of polishing liquids by using abrasive grains having various shapes and various organic compounds as additives. The insulating material was polished by using these polishing liquids, and the polishing characteristics were evaluated. As a result, the present inventors have found that a polishing liquid excellent in step height elimination characteristics for an insulating material having irregularities is obtained by using an abrasive grain having a specific shape, and a compound having a specific chemical structure as an additive.

The first embodiment of the CMP polishing liquid of the present invention is a CMP polishing liquid for polishing an insulating material, comprising a cerium oxide particle satisfying the conditions (A) and (B) below, a 4-pyrone-based compound represented by the general formula (1) below, and water,

condition (A): an average particle diameter R of the cerium oxide particle is 50 nm or more and 300 nm or less, and

condition (B): when the cerium oxide particle is defined as a spherical particle having the average particle diameter R, sphericity S2/S1 provided by a specific surface area S1 of the spherical particle and a specific surface area S2 of the cerium oxide particle measured by the BET method is 3.15 or less.

### [Chemical Formula 1]

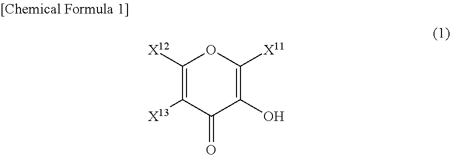

[In the formula, X¹¹, X¹² and X¹³ are each independently a hydrogen atom or a monovalent substituent.]

According to the CMP polishing liquid of the first embodiment, it is possible to obtain excellent step height elimination characteristics for the insulating material having irregularities, and a high polishing rate of the convex regions and a large polishing rate ratio between the convex regions and the concave regions can be obtained in the polishing of the insulating material having irregularities on the surface thereof. Such a CMP polishing liquid is suitable for polishing the insulating material having irregularities, and the irregularities (step height) of the insulating material having irregularities can be efficiently eliminated. Also, according to the CMP polishing liquid of the first embodiment, the insulating material having no irregularities can be polished at a satisfactory polishing rate.

Also, according to the CMP polishing liquid of the first embodiment, a high polishing rate can be achieved without significantly depending on the state of the surface to be polished. Therefore, the CMP polishing liquid of the first embodiment has the advantage that even a semiconductor material, for which it is relatively difficult to obtain a high polishing rate by means of conventional polishing liquids, can be polished at a high rate. The CMP polishing liquid of the first embodiment can exert excellent polishing characteristics in the case of polishing an insulating material of the surface having T-shaped or lattice shaped concave regions or convex regions, for example, a semiconductor substrate having a memory cell.

Although a factor responsible for these effects is not clear, the present inventor presumes as follows: small sphericity S2/S1 to some extent means that the shape of the particle is close to a complete globe (sphere). In the case of such a particle whose sphericity is small, the number of particles that can come in contact with the surface to be polished is presumed to be increased as compared with a particle whose shape is not close to a sphere. That is, a chemical bonding site between the abrasive grain and the surface of the insulating material is presumed to become large in number.

In such a state where the bonding site between the abrasive grain and the insulating material is large in number, the polishing liquid comprises a 4-pyrone-based compound having a specific chemical structure to thereby increase the interaction between the abrasive grain and the insulating material. As a result, the polishing of the convex regions which are placed under a higher load (under a stronger frictional force) as compared with the concave regions during the polishing is presumed to proceed efficiently.

It is presumed that: in such a state where the bonding site between the abrasive grain and the insulating material is large in number, the interaction between the abrasive grain and the insulating material is large due to the influence of the 4-pyrone-based compound, and therefore, the frictional force is easily applied to the convex regions; on the other hand, as the frictional force applied to the concave regions, the flat surface of the insulating material in a state where the step height are decreased in size, and the like, is weaker than the frictional force applied to the convex regions, and therefore, the polishing of the concave regions and the flat surface does not proceed relatively. This is probably because the interaction between the abrasive grain and the insulating material is large due to the influence of the 4-pyrone-based compound in the state where the bonding site between the abrasive grain and the insulating material is large in number, and therefore, assuming that the insulating material is then removed by the physical effect of the abrasive grain or by a physical effect such as a load to be applied to a polishing pad or a wafer, the strong interaction between the abrasive grain and the insulating material is presumed to rather inhibit the polishing capability as these physical effects are weakened.

In the polishing of the insulating material having irregularities, there is the case of adjusting the polishing of the insulating material by using a stopper (polishing stop layer including a stopper material) disposed on the convex regions of the substrate. In this case, for obtaining flat surface, it is necessary to selectively polish the insulating material with respect to the stopper material, and therefore, a high stopping property of the stopper material with respect to the insulating material (ratio of the polishing rate of the insulating material with respect to the polishing rate of the stopper material) is desired.

The present inventors made a diligent study on the abrasive grain and the additives to be comprised in the CMP polishing liquid in order to solve the above problems. The present inventors prepared a large number of polishing liquids by using abrasive grains having various shapes and various organic compounds as additives. The insulating material and the stopper material were polished by using these polishing liquids, and the polishing characteristics were evaluated. As a result, the present inventors have found that a polishing liquid excellent in step height elimination characteristics for an insulating material having irregularities and also excellent in the stopping property of a stopper material is obtained by using an abrasive grain having a specific shape, and a specific compound as an additive.

The second embodiment of the CMP polishing liquid of the present invention is a CMP polishing liquid for polishing an insulating material, comprising a cerium oxide particle satisfying the conditions (A) and (B) below, a 4-pyrone-based compound represented by the general formula (1) below, a polymer compound having an aromatic ring and a polyoxyalkylene chain, a cationic polymer, and water,

condition (A): an average particle diameter R of the cerium oxide particle is 50 nm or more and 300 nm or less, and

condition (B): when the cerium oxide particle is defined as a spherical particle having the average particle diameter R, sphericity S2/S1 provided by a specific surface area S1 of the spherical particle and a specific surface area S2 of the cerium oxide particle measured by the BET method is 3.15 or less.

### [Chemical Formula 2]

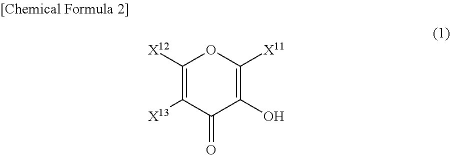

[In the formula, X¹¹, X¹² and X¹³ are each independently a hydrogen atom or a monovalent substituent.]

According to the CMP polishing liquid of the second embodiment, it is possible to obtain excellent step height elimination characteristics for the insulating material having irregularities, and a high polishing rate of the convex regions and a large polishing rate ratio between the convex regions and the concave regions can be obtained in the polishing of the insulating material having irregularities on the surface thereof. Such a CMP polishing liquid is suitable for polishing the insulating material having irregularities, and the irregularities (step height) of the insulating material having irregularities can be efficiently eliminated. Also, according to the CMP polishing liquid of the second embodiment, the insulating material having no irregularities can be polished at a satisfactory polishing rate.

Also, according to the CMP polishing liquid of the second embodiment, a high polishing rate can be achieved without significantly depending on the state of the surface to be polished. Therefore, the CMP polishing liquid of the second embodiment has the advantage that even a semiconductor material, for which it is relatively difficult to obtain a high polishing rate by means of conventional polishing liquids, can be polished at a high rate. The CMP polishing liquid of the second embodiment can exert excellent polishing characteristics in the case of polishing an insulating material of the surface having T-shaped or lattice shaped concave regions or convex regions, for example, a semiconductor substrate having a memory cell.

Although a factor responsible for these effects of the second embodiment is not clear, the present inventor presumes as mentioned above about the first embodiment.

In addition, according to the CMP polishing liquid of the second embodiment, a high stopping property of the stopper material with respect to the insulating material can be obtained. Although a factor responsible for such an effect is not clear, it is presumed that the polymer compound having an aromatic ring and a polyoxyalkylene chain and the cationic polymer cover the stopper material to thereby electrostatically and sterically inhibit the contact between the abrasive grain and the stopper material, and therefore, a high stopping property is achieved.

According to the CMP polishing liquid of the second embodiment, as described above, excellent step height elimination characteristics for the insulating material having irregularities can be obtained, and a high stopping property of the stopper material can be obtained. Such a CMP polishing liquid is suitable for polishing the insulating material having irregularities by using the stopper including a stopper material. In addition, the CMP polishing liquid of the second embodiment exerts excellent polishing characteristics, particularly, in the case where the stopper material is polysilicon.

It is preferable that a pH of the CMP polishing liquid of the present invention is less than 8.0. This facilitates the suppression of the aggregation of the abrasive grain and the like while the effect of the addition of the additives is easily obtained.

It is preferable that a zeta potential of the cerium oxide particle in the CMP polishing liquid of the present invention is positive. This can easily obtain a high polishing rate of the insulating material.

It is preferable that the 4-pyrone-based compound is at least one selected from the group consisting of 3-hydroxy-2-methyl-4-pyrone, 5-hydroxy-2-(hydroxymethyl)-4-pyrone, and 2-ethyl-3-hydroxy-4-pyrone. This can obtain further excellent step height elimination characteristics and facilitates the achievement of a high stopping property of the stopper material.

It is preferable that the CMP polishing liquid of the present invention further comprises a saturated monocarboxylic acid having 2 to 6 carbon atoms. This allows the insulating material having no irregularities to be polished at a more satisfactory polishing rate. Also, this can enhance the polishing rate of the insulating material having no irregularities without reducing the polishing rate of the insulating material having irregularities, and enhance in-plane uniformity which is an index for uneven polishing rates within the surface to be polished.

It is preferable that the saturated monocarboxylic acid is at least one selected from the group consisting of acetic acid, propionic acid, butyric acid, isobutyric acid, valeric acid, isovaleric acid, pivalic acid, hydroangelic acid, caproic acid, 2-methylpentanoic acid, 4-methylpentanoic acid, 2,3-dimethylbutanoic acid, 2-ethylbutanoic acid, 2,2-dimethylbutanoic acid, and 3,3-dimethylbutanoic acid. The enhancement effect of the polishing rate of the insulating material having no irregularities and the enhancement effect of in-plane uniformity are thereby obtained more satisfactorily.

The CMP polishing liquid of the present invention may comprise a pH adjuster.

The present invention provides a polishing method for polishing an insulating material by using the above-mentioned CMP polishing liquid. That is, the polishing method of the present invention is a polishing method for polishing a substrate having an insulating material on the surface thereof, the polishing method comprising a step of polishing the insulating material by using the above-mentioned CMP polishing liquid.

According to such a polishing method, it is possible to obtain excellent step height elimination characteristics for the insulating material having irregularities, and a high polishing rate of the convex regions and a large polishing rate ratio between the convex regions and the concave regions can be obtained in the polishing of the insulating material having irregularities on the surface thereof. Such a polishing method is suitable for polishing the insulating material having irregularities, and the irregularities (step height) of the insulating material having irregularities can be efficiently eliminated. Also, according to the polishing method of the present invention, the insulating material having no irregularities can be polished at a satisfactory polishing rate.

The surface of the substrate may have T-shaped or lattice shaped concave regions or convex regions. Also, the substrate may be a semiconductor substrate having a memory cell.

### Advantageous Effects of Invention

According to the present invention, it is possible to obtain excellent step height elimination characteristics for the insulating material having irregularities, and a high polishing rate of the convex regions and a large polishing rate ratio between the convex regions and the concave regions can be obtained in the polishing of the insulating material having irregularities on the surface thereof. This can obtain a substrate excellent in flatness by preferentially polishing the convex regions in the polishing of the insulating material of a substrate including the insulating material having irregularities on the surface thereof. Also, according to the present invention, the insulating material having no irregularities can be polished at a satisfactory polishing rate.

According to the present invention, it is possible to provide use of the CMP polishing liquid in the polishing of an insulating material, and particularly, use of the CMP polishing liquid in the polishing of an insulating material having irregularities can be provided. According to the present invention, use of the CMP polishing liquid in the polishing of a semiconductor material (e.g., a semiconductor substrate) can be provided. According to the present invention, use of the CMP polishing liquid in the polishing of surface having T-shaped or lattice shaped concave regions or convex regions can be provided. According to the present invention, use of the CMP polishing liquid in the polishing of a semiconductor substrate having a memory cell can be provided.

### BRIEF DESCRIPTION OF DRAWINGS

FIG. 1 is a schematic cross-sectional view illustrating the process for forming a shallow trench isolation structure on a substrate by polishing an insulating material.

FIG. 2 is a schematic cross-sectional view illustrating an evaluation substrate of polishing characteristics.

### DESCRIPTION OF EMBODIMENTS

Hereinafter, the CMP polishing liquid of an embodiment of the present invention, and a polishing method using the CMP polishing liquid will be described.

### Definition

In the present specification, the term “step” not only includes an independent step but includes a step that cannot be clearly distinguished from the other steps as long as the intended effect of the step is achieved.

In the present specification, a numerical range represented by using “to” means a range including the numerical values presented before and after “to” as the minimum value and the maximum value, respectively.

In the present specification, in the case where a plurality of substances corresponding to each of the components are present in a composition, unless otherwise specified, the amount of each of the components in the composition means the total amount of the plurality of substances present in the composition.

In the present specification, the “polishing rate” means the rate at which a material is removed per unit time (removal rate).

In the present specification, the phrase “selectively remove a material A with respect to a material B” means that the material A is more preferentially removed than the material B. More specifically, in the case where a material A and a material B coexist with each other, it means that the material A is more preferentially removed than the material B.

In the present specification, the term “present embodiment” encompasses the first embodiment and the second embodiment.

<CMP Polishing Liquid>

The CMP polishing liquid of the present embodiment comprises an abrasive grain (polishing particle), an additive, and water. A feature of the CMP polishing liquid of the present embodiment is that a particle having a specific shape is used as the abrasive grain and a compound having a specific chemical structure is used as the additive.

The CMP polishing liquid of the present embodiment is a CMP polishing liquid for polishing an insulating material. The CMP polishing liquid of the first embodiment comprises a cerium oxide particle satisfying the conditions (A) and (B) below, a 4-pyrone-based compound represented by the general formula (1) below, and water. The CMP polishing liquid of the second embodiment comprises a cerium oxide particle satisfying the conditions (A) and (B) below, a 4-pyrone-based compound represented by the general formula (1) below, a polymer compound having an aromatic ring and a polyoxyalkylene chain (aromatic polyoxyalkylene compound), a cationic polymer, and water.

Condition (A): an average particle diameter R of the cerium oxide particle is 50 nm or more and 300 nm or less.

Condition (B): when the cerium oxide particle is defined as a spherical particle having the average particle diameter R, sphericity S2/S1 provided by a specific surface area S1 of the spherical particle and a specific surface area S2 of the cerium oxide particle measured by the BET method is 3.15 or less.

### [Chemical Formula 3]

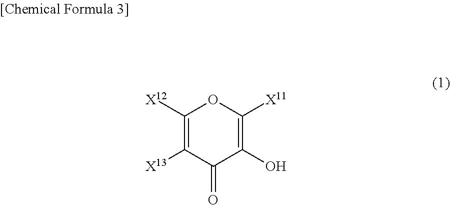

[In the formula, X¹¹, X¹² and X¹³ are each independently a hydrogen atom or a monovalent substituent.]

According to the CMP polishing liquid of the present embodiment, it is possible to obtain excellent step height elimination characteristics for the insulating material having irregularities, and a high polishing rate of the convex regions and a large polishing rate ratio between the convex regions and the concave regions can be obtained in the polishing of the insulating material having irregularities on the surface thereof. This can obtain a substrate excellent in flatness by preferentially polishing the convex regions in the polishing of the insulating material of a substrate including the insulating material having irregularities on the surface thereof. Also, according to the CMP polishing liquid of the second embodiment, a high stopping property of the stopper material can be obtained. Such a CMP polishing liquid is suitable for polishing the insulating material having irregularities by using a stopper including a stopper material.

According to the present embodiment, it is possible to provide use of the CMP polishing liquid in the polishing of an insulating material, and particularly, use of the CMP polishing liquid in the polishing of an insulating material having irregularities can be provided. According to the present embodiment, use of the CMP polishing liquid in the polishing of an insulating material using a stopper including a stopper material can be provided. According to the present embodiment, use of the CMP polishing liquid in the polishing of an insulating material using a stopper including polysilicon can be provided. According to the present embodiment, use of the CMP polishing liquid in, for example, the preparation of a STI structure of a flash memory with polysilicon as a stopper material can be provided.

Hereinafter, each component and the like used in the CMP polishing liquid of the present embodiment will be described.

(Abrasive Grain)

As the abrasive grain, a cerium oxide particle is used. The CMP polishing liquid using the cerium oxide particle as the abrasive grain has a feature that the polishing scratches occurring on the polished surface are relatively small in number.

The abrasive grain used in the CMP polishing liquid of the present embodiment is a cerium oxide particle satisfying the conditions (A) and (B) below. By using such an abrasive grain, excellent step height elimination characteristics can be obtained.

Condition (A): an average particle diameter R of the cerium oxide particle is 50 nm or more and 300 nm or less.

Condition (B): when the cerium oxide particle is defined as a spherical particle having the average particle diameter R, sphericity S2/S1 provided by a specific surface area S1 of the spherical particle and a specific surface area S2 of the cerium oxide particle measured by the BET method is 3.15 or less.

[Condition (A): Average Particle Diameter R]

The average particle diameter R is obtained by measurement, for example, in the monodisperse mode of a submicron particle analyzer “N5” manufactured by Beckman Coulter, Inc. For example, measurement for 240 seconds is performed by using a water dispersion of the cerium oxide particle obtained by adjusting (dilution with water) intensity (signal intensity) obtained from the submicron particle analyzer “N5” manufactured by Beckman Coulter, Inc. to within the range of 1.0E+4 to 1.0E+6, and the obtained results can be used as the average particle diameter R.

The average particle diameter R is 50 nm or more and 300 nm or less, as described above, from the viewpoint of obtaining excellent step height elimination characteristics. Also, when the average particle diameter R is 300 nm or less, the occurrence of polishing scratches can be easily reduced to a low level. The lower limit of the average particle diameter R is preferably 60 nm or more, more preferably 70 nm or more, further preferably 80 nm or more, particularly preferably 90 nm or more, extremely preferably 100 nm or more, very preferably 120 nm or more, much more preferably 130 nm or more, from the viewpoint that a high polishing rate of the insulating material is easily obtained. The upper limit of the average particle diameter R is preferably 280 nm or less, more preferably 260 nm or less, further preferably 250 nm or less, particularly preferably 220 nm or less, extremely preferably 200 nm or less, very preferably 180 nm or less, much more preferably 150 nm or less, from the viewpoint of reducing the aggregation of the abrasive grain or the frequency of occurrence of polishing scratches.

[Condition (B): Sphericity S2/S1]

In the present embodiment, when the cerium oxide particle is defined as a spherical particle having the average particle diameter R, sphericity S2/S1 provided by a specific surface area S1 of the spherical particle and a specific surface area S2 of the cerium oxide particle measured by the BET method is 3.15 or less. In other words, a value obtained by dividing the specific surface area S1 of a virtual cerium oxide particle (virtual spherical particle) having the average particle diameter R of the condition (A) and having a completely spherical shape by the specific surface area S2 measured by the BET method (S2/S1: sphericity) is 3.15 or less. In these cases, the polishing rate ratio between the convex regions and the concave regions can be sufficiently increased.

The specific surface area S1 [m²/g] of the spherical particle having the average particle diameter R is determined by 4π(R/2)²/((4/3)π(R/2)³×d) based on the average particle diameter R [m] and a density d [g/m³] of cerium oxide. Herein, as the density d of cerium oxide, for example, 7.2×10⁶ [g/m³] can be adopted.

The specific surface area S2 is a measurement value of the specific surface area (surface area per unit mass) of the particle actually measured by the BET method. In the BET method, an adsorbate (e.g., an inert gas such as nitrogen) is physically adsorbed to solid particle surface at a low temperature, and the specific surface area can be estimated from the molecular cross-sectional area and adsorbed amount of the adsorbate.

Specifically, the specific surface area S2 can be measured by the following procedures: first, 100 g of a water dispersion of the cerium oxide particle (content of the cerium oxide particle: approximately 5 mass %) is placed in a dryer and then dried at 150° C. to obtain the cerium oxide particle. Approximately 0.4 g of the obtained cerium oxide particle is placed in a measurement cell of a BET specific surface area measurement apparatus and then degassed in vacuum at 150° C. for 60 minutes. As the BET specific surface area measurement apparatus, for example, NOVA-1200 (manufactured by Yuasa Ionics Co., Ltd.), which is a gas adsorption-type specific surface area/pore distribution measurement apparatus, can be used. In this case, a value obtained as “Area” by measurement according to the constant volume method using nitrogen gas as an adsorption gas can be obtained as a BET specific surface area. The measurement is performed twice, and an average value thereof can be determined as the specific surface area S2.

According to the BET theory, a physical molecular adsorption amount v at an adsorption equilibrium pressure P is represented by the following expression (2):

v=vₘcP/(Pₛ−P)(1−(P/Pₛ)+c(P/Pₛ)) (2)

[Pₛ is the saturated vapor pressure of the adsorbate gas at the measurement temperature, vₘ is a monomolecular adsorption amount (mol/g), and c is a constant.]

By varying the expression (2), the following expression (3) is obtained.

P/v(Pₛ−P)=1/vₘc+(c−1)/vₘc·P/Pₛ (3)

According to the expression (3), a straight line is obtained by plotting P/v(Pₛ−P) against the relative pressure P/Pₛ. P/v(Pₛ−P) is measured at 3 relative pressures, for example, 0.1, 0.2 and 0.3, and then, these 3 points are plotted to obtain a straight line. vₘ is determined from the slope and intercept of the obtained straight line, and then, vₘ is multiplied by the occupied area [m²] and Avogadro's number [the number of molecules/mol] of nitrogen molecules to obtain a specific surface area. The total sum of surface areas per unit mass of particles contained in a powder is the specific surface area.

Then, the value S2/S1 obtained by dividing the measurement value S2 of the specific surface area of the cerium oxide particle measured by the BET method by the theoretical value S1 of the specific surface area of the spherical virtual cerium oxide particle is determined as the sphericity.

The upper limit of the sphericity S2/S1 is 3.15 or less, as described above, from the viewpoint of obtaining excellent step height elimination characteristics. The upper limit of the sphericity S2/S1 is preferably 3.10 or less, more preferably 3.05 or less, further preferably 2.98 or less, particularly preferably 2.90 or less, from the viewpoint of obtaining further excellent step height elimination characteristics. The lower limit of the sphericity S2/S1 is preferably 1.00 or more, more preferably 1.50 or more.

It is preferable that the zeta potential of the cerium oxide particle in the CMP polishing liquid is positive (exceed 0 mV). Since the electric attraction between the cerium oxide particle and the insulating material thereby works, the cerium oxide particle can more efficiently approach the insulating material. Therefore, the polishing proceeds more efficiently, and a high polishing rate of the insulating material can therefore be easily obtained. Particularly, even in the case of using a particle having a small particle diameter to some extent, a high polishing rate of the insulating material can be easily obtained. The lower limit of the zeta potential of the abrasive grain in the present embodiment is more preferably 1 mV or more, further preferably 5 mV or more, particularly preferably 10 mV or more, extremely preferably 15 mV or more, from the viewpoint of easily obtaining a higher polishing rate of the insulating material. The lower limit of the zeta potential of the abrasive grain in the second embodiment is very preferably 20 mV or more, much more preferably 30 mV or more, from the viewpoint of easily obtaining a higher polishing rate of the insulating material. The upper limit of the zeta potential of the abrasive grain is not particularly limited, but is, for example, 100 mV.

The zeta potential is generally measured with an apparatus using an electrophoresis scheme. For example, the zeta potential can be measured with an apparatus such as Zetasizer 3000 HSA (manufactured by Malvern Instruments Ltd.) or Delsa Nano C (manufactured by Beckman Coulter, Inc.).

The lower limit of the content of the cerium oxide particle satisfying the conditions (A) and (B) is preferably 0.05 mass % or more, more preferably 0.075 mass % or more, further preferably 0.10 mass % or more, particularly preferably 0.15 mass % or more, extremely preferably 0.20 mass % or more, very preferably 0.25 mass % or more, based on the total mass of the CMP polishing liquid from the viewpoint of obtaining a higher polishing rate of the insulating material. The upper limit of the content of the cerium oxide particle is preferably 10 mass % or less, more preferably 7 mass % or less, further preferably 5 mass % or less, particularly preferably 3 mass % or less, extremely preferably 2 mass % or less, very preferably 1 mass % or less, based on the total mass of the CMP polishing liquid from the viewpoint of reducing the aggregation of the abrasive grain or the frequency of occurrence of polishing scratches.

The CMP polishing liquid of the present embodiment may employ the cerium oxide particle and other particle in combination as the abrasive grain. Examples of a constituent material for such a particle include: oxides such as silica, alumina and zirconia; hydroxides of cerium and the like; and resins. These particles may be used each alone or may be used in combination of two or more.

The lower limit of the content of the abrasive grain is preferably 0.05 mass % or more, more preferably 0.075 mass % or more, further preferably 0.10 mass % or more, particularly preferably 0.15 mass % or more, extremely preferably 0.20 mass % or more, very preferably 0.25 mass % or more, based on the total mass of the CMP polishing liquid from the viewpoint of obtaining a higher polishing rate of the insulating material. The upper limit of the content of the abrasive grain is preferably 10 mass % or less, more preferably 7 mass % or less, further preferably 5 mass % or less, particularly preferably 3 mass % or less, extremely preferably 2 mass % or less, very preferably 1 mass % or less, based on the total mass of the CMP polishing liquid from the viewpoint of reducing the aggregation of the abrasive grain or the frequency of occurrence of polishing scratches.

The content of the cerium oxide particle satisfying the conditions (A) and (B) is preferably 50 mass % or more, more preferably 60 mass % or more, further preferably 70 mass % or more, particularly preferably 80 mass % or more, extremely preferably 90 mass % or more, very preferably 95 mass % or more, much more preferably 98 mass % or more, further preferably 99 mass % or more, based on the total mass of the abrasive grain. It is particularly preferable that the abrasive grain is composed of the cerium oxide particle satisfying the conditions (A) and (B) (all of abrasive grains are substantially cerium oxide particles satisfying the conditions (A) and (B)).

(First Additive: 4-Pyrone-Based Compound)

The CMP polishing liquid of the present embodiment comprises a 4-pyrone-based compound represented by the general formula (1) below as a first additive. The first additives may be used each alone or may be used in combination of two or more.

### [Chemical Formula 4]

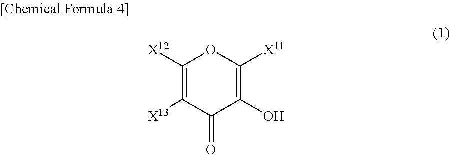

[In the formula, X¹¹, X¹² and X¹³ are each independently a hydrogen atom or a monovalent substituent.]

By using the 4-pyrone-based compound and the cerium oxide particle in combination, excellent step height elimination characteristics are effectively obtained. Although a factor responsible for such an effect is not clear, the present inventor presumes as follows: first, as mentioned above, in the case of a particle whose sphericity S2/S1 is small, the number of particles that can come in contact with the surface to be polished is increased as compared with a particle whose shape is not close to a sphere, and therefore, a chemical bonding site between the abrasive grain and the surface of the insulating material is presumed to become large in number. In such a state where the bonding site between the abrasive grain and the insulating material is large in number, the interaction between the abrasive grain and the insulating material is increased by using the 4-pyrone-based compound having the specific structure mentioned above as an additive. As a result, the polishing of the convex regions which are placed under a higher load (under a stronger frictional force) as compared with the concave regions during the polishing is presumed to proceed efficiently. It is presumed that: in such a state where the bonding site between the abrasive grain and the insulating material is large in number, the interaction between the abrasive grain and the insulating material is large due to the influence of the 4-pyrone-based compound, and therefore, the frictional force is easily applied to the convex regions; on the other hand, as the frictional force applied to the concave regions, the flat surface of the insulating material in a state where the step height are decreased in size, and the like, is weaker than the frictional force applied to the convex regions, and therefore, the polishing of the concave regions and the flat surface does not proceed relatively.

The present inventors prepared a large number of polishing liquids by using various organic compounds as additives and then performed the measurement of particle diameters over time in order to examine the presence or absence of the aggregation of abrasive grains comprised in the polishing liquids. As a result, the present inventors have found that when the polishing liquid comprises the 4-pyrone-based compound as an additive among the organic compounds, the effect of being able to suppress the aggregation of the abrasive grain is exerted in addition to the effect mentioned above. It is considered that, even though such a 4-pyrone-based compound is an additive capable of increasing the interaction between the abrasive grain and the insulating material, it has no effect of weakening the repulsion, such as electrostatic repulsion, between abrasive grains and can therefore suppress the aggregation of the abrasive grain.

The 4-pyrone-based compound of the present embodiment has a structure in which a hydroxy group is bonded to at least a carbon atom adjacent to the carbon atom of the carbonyl group. Herein, the “4-pyrone-based compound” is a heterocyclic compound having a six-membered ring (γ-pyrone ring) structure which includes an oxy group and a carbonyl group and in which the carbonyl group is located at the 4-position relative to the oxy group. In the 4-pyrone-based compound of the present embodiment, a hydroxy group is bonded to the carbon atom adjacent to the carbonyl group of this 7-pyrone ring, and the other carbon atoms may be substituted by a substituent other than a hydrogen atom.

Examples of the monovalent substituent include an aldehyde group, a hydroxy group, a carboxyl group, a sulfonate group, a phosphate group, a bromine atom, a chlorine atom, an iodine atom, a fluorine atom, a nitro group, a hydrazine group, an alkyl group (optionally substituted with OH, COOH, Br, Cl, I or NO₂; a hydroxyalkyl group and the like), an aryl group, and an alkenyl group. The number of carbon atoms in the alkyl group is, for example, 1 to 8. The number of carbon atoms in the aryl group is, for example, 6 to 12. The number of carbon atoms in the alkenyl group is, for example, 1 to 8. As the monovalent substituent, a methyl group, an ethyl group and a hydroxymethyl group are preferable.

In the case of having a monovalent substituent as X¹¹, X¹² and X¹³, it is preferable that the monovalent substituent is bonded to a carbon atom adjacent to the oxy group from the viewpoint that the synthesis is simple, i.e., it is preferable that at least one of X¹¹ and X¹² is a monovalent substituent. In addition, from the viewpoint that the enhancement effect of the polishing capability of the abrasive grain is easily obtained, it is preferable that at least two of X¹¹, X¹² and X¹³ are hydrogen atoms, and it is more preferable that two of X¹¹, X¹² and X¹³ are hydrogen atoms.

As the first additive, at least one compound selected from the group consisting of 3-hydroxy-2-methyl-4-pyrone (another name: 3-hydroxy-2-methyl-4H-pyran-4-one or maltol), 5-hydroxy-2-(hydroxymethyl)-4-pyrone (another name: 5-hydroxy-2-(hydroxymethyl)-4H-pyran-4-one), and 2-ethyl-3-hydroxy-4-pyrone (another name: 2-ethyl-3-hydroxy-4H-pyran-4-one) is preferred, and at least one compound selected from the group consisting of 3-hydroxy-2-methyl-4-pyrone and 5-hydroxy-2-(hydroxymethyl)-4-pyrone is more preferred, from the viewpoint of obtaining further excellent step height elimination characteristics. These compounds may be used each alone or may be used in combination of two or more. By comprising two or more of these compounds in combination, the effect of further enhancing the polishing rate of the insulating material having no irregularities and the effect of enhancing in-plane uniformity can be obtained.

It is preferable that the first additive is water soluble. By using a compound having high solubility in water, it is possible to satisfactorily dissolve a desired amount of the first additive in the polishing liquid, and the enhancement effect of the polishing rate and the suppression effect of the aggregation of the abrasive grain can be obtained at further higher levels. The lower limit of the solubility of the first additive in 100 g of water at normal temperature (25° C.) is preferably 0.001 g or more, more preferably 0.005 g or more, further preferably 0.01 g or more, particularly preferably 0.05 g or more. Herein, the upper limit of the solubility is not particularly limited.

The lower limit of the content of the first additive is preferably 0.001 mass % or more, more preferably 0.005 mass % or more, further preferably 0.01 mass % or more, particularly preferably 0.015 mass % or more, based on the total mass of the CMP polishing liquid. When the content of the first additive is 0.001 mass % or more, a stable polishing rate is more easily achieved as compared with the case of less than 0.001 mass %. The upper limit of the content of the first additive is preferably 5 mass % or less, more preferably 3 mass % or less, further preferably 1 mass % or less, particularly preferably 0.50 mass % or less, extremely preferably 0.30 mass % or less, very preferably 0.20 mass % or less, much more preferably 0.10 mass % or less, based on the total mass of the CMP polishing liquid. When the content of the first additive is 5 mass % or less, the aggregation of the abrasive grain is more easily suppressed and a high polishing rate of the insulating material is more easily achieved as compared with the case of exceeding 5 mass %.

(Second Additive: Aromatic Polyoxyalkylene Compound)

The aromatic polyoxyalkylene compound has, for example, an effect of inhibiting the polishing rate of the stopper material from being excessively increased. The reason why this effect is exerted is presumed as follows: the aromatic polyoxyalkylene compound covers the stopper material to thereby suppress polishing of the stopper material. Such an effect is more remarkably achieved in the case where the stopper material is polysilicon.

The aromatic polyoxyalkylene compound is a compound in which a substituent having an aromatic ring is introduced to the terminal of a polyoxyalkylene. The aromatic ring may be directly bonded or may not be directly bonded to the polyoxyalkylene chain. The aromatic ring may be monocyclic or may be polycyclic. In addition, the aromatic polyoxyalkylene compound may have a structure in which a plurality of polyoxyalkylene chains are bonded via a substituent having an aromatic ring. The polyoxyalkylene chain is preferably a polyoxyethylene chain, a polyoxypropylene chain, or a polyoxyethylene-polyoxypropylene chain from the viewpoint that the synthesis is simple. The number of structure units in the polyoxyalkylene chain (the number of structure units of the oxyalkylene structure) is preferably 15 or more from the viewpoint of efficiently covering the stopper material.

Examples of the substituent having an aromatic ring include an aryl group, in the case where the aromatic ring is positioned at the terminal of the aromatic polyoxyalkylene compound. Examples of the aryl group include: monocyclic aromatic groups such as a phenyl group, a benzyl group, a tolyl group, and a xylyl group; and polycyclic aromatics such as a naphthyl group, and such aromatic groups may further have a substituent. Examples of the substituent introduced to the aromatic group include an alkyl group, a vinyl group, an allyl group, an alkenyl group, an alkynyl group, an alkoxy group, a halogeno group, a hydroxy group, a carbonyl group, a nitro group, an amino group, a styrene group, and an aromatic group, and an alkyl group and a styrene group are preferable from the viewpoint of efficiently covering the stopper material.

Examples of the substituent having an aromatic ring include an arylene group, in the case where the aromatic ring is positioned in the main chain of the aromatic polyoxyalkylene compound. Examples of the arylene group include: monocyclic aromatic groups such as a phenylene group, a tolylene group, and a xylylene group; and polycyclic aromatics such as a naphthylene group, and such aromatic groups may further have a substituent. Examples of the substituent introduced to the aromatic group include an alkyl group, a vinyl group, an allyl group, an alkenyl group, an alkynyl group, an alkoxy group, a halogeno group, a hydroxy group, a carbonyl group, a nitro group, an amino group, a styrene group, and an aromatic group.

It is preferable that the aromatic polyoxyalkylene compound is a compound represented by the following general formula (I) or the following general formula (II) from the viewpoint of efficiently covering the stopper material.

R¹¹—O—(R¹²—O)ₘ—H (I)

[In the formula (I), R¹¹ represents an aryl group optionally having a substituent, R¹² represents an alkylene group having 1 to 5 carbon atoms and optionally having a substituent, and m represents an integer of 15 or more.]

H—(O—R¹²)ₙ₁—O—R²¹—R²⁵—R²²—O—(R²⁴—O)ₙ₂—H (II)

[In the formula (II), R²¹ and R²² each independently represent an arylene group optionally having a substituent, R²³, R²⁴ and R²⁵ each independently represent an alkylene group having 1 to 5 carbon atoms and optionally having a substituent, and n1 and n2 each independently represent an integer of 15 or more.]

From the viewpoint that the polishing selectivity for the insulating material with respect to the stopper material is further enhanced, it is preferable that the formula (I) or formula (II) satisfies at least one of the following conditions.
As R¹¹, the aryl group shown as an example of the substituent having an aromatic ring is preferable, and a phenyl group to which a styrene group or an alkyl group is introduced as a substituent is more preferable.
As R²¹ and R²², the arylene group shown as an example of the substituent having an aromatic ring is preferable.
As R¹², R²³, R²⁴ and R²⁵, an ethylene group or a n-propylene group is preferable.
m is preferably 15 or more, more preferably 30 or more.
m is preferably 20000 or less, more preferably 10000 or less, further preferably 5000 or less, particularly preferably 1000 or less.
n1 and n2 are preferably 15 or more, more preferably 30 or more.
n1 and n2 are preferably 20000 or less, more preferably 10000 or less, further preferably 5000 or less, particularly preferably 1000 or less.

Examples of the aromatic polyoxyalkylene compound represented by the formula (I) include polyoxyalkylene phenyl ether, polyoxyalkylene alkylphenyl ether, polyoxyalkylene styrenated-phenyl ether, polyoxyalkylene cumylphenyl ether, and polyoxyalkylene benzyl ether. Specifically, examples of the aromatic polyoxyalkylene compound represented by the formula (I) include polyoxyethylene alkylphenyl ether (e.g., Emulsit series manufactured by Dai-Ichi Kogyo Seiyaku Co., Ltd.), polyoxyethylene nonylpropenylphenyl ether (e.g., Aqualon RN series manufactured by Dai-Ichi Kogyo Seiyaku Co., Ltd.), polyoxyethylene phenyl ether, polyoxyethylene styrenated-phenyl ether (e.g., Emulgen A-500 manufactured by Kao Corporation; and Noigen EA-7 series manufactured by Dai-Ichi Kogyo Seiyaku Co., Ltd.), polyoxypropylene phenyl ether, polyoxyethylene cumylphenyl ether, and polyoxyethylene benzyl ether. Examples of the aromatic polyoxyalkylene compound represented by the formula (II) include 2,2-bis(4-polyoxyethylene oxyphenyl)propane.

The aromatic polyoxyalkylene compounds can be used each alone or in combination of two or more for the purpose of adjusting polishing characteristics such as polishing selectivity and flatness.

The lower limit of the weight average molecular weight of the aromatic polyoxyalkylene compound is preferably 1000 or more, more preferably 1500 or more, further preferably 2000 or more, particularly preferably 4000 or more, from the viewpoint of having further excellent polishing selectivity. The upper limit of the weight average molecular weight of the aromatic polyoxyalkylene compound is preferably 1000000 or less, more preferably 500000 or less, further preferably 250000 or less, particularly preferably 100000 or less, extremely preferably 50000 or less, very preferably 10000 or less, much more preferably 8000 or less, further preferably, 5000 or less, from the viewpoint of having further excellent polishing selectivity.

Herein, the weight average molecular weight of the aromatic polyoxyalkylene compound can be measured, for example, by the gel permeation chromatography method (GPC) under the following conditions using the calibration curve of standard polystyrene.

Instrument used: Hitachi L-6000 Model [manufactured by Hitachi Ltd.]

Column: Gel-Pak GL-R420+Gel-Pak GL-R430+Gel-Pak GL-R440 [manufactured by Hitachi Chemical Co., Ltd., trade names, three columns in total]

Eluent: tetrahydrofuran

Measurement temperature: 40° C.

Flow rate: 1.75 mL/min

Detector: L-3300R1 [manufactured by Hitachi Ltd.]

The content of the aromatic polyoxyalkylene compound is preferably 0.01 mass % or more based on the total mass of the CMP polishing liquid. This can further suppress the polishing rate of the stopper material. From the same viewpoint as above, the lower limit of the content of the aromatic polyoxyalkylene compound is more preferably 0.05 mass % or more, further preferably 0.10 mass % or more, particularly preferably 0.20 mass % or more, extremely preferably 0.25 mass % or more, based on the total mass of the CMP polishing liquid. The upper limit of the content of the aromatic polyoxyalkylene compound is not particularly limited, but is preferably 10 mass % or less, more preferably 5 mass % or less, further preferably 3 mass % or less, particularly preferably 2 mass % or less, extremely preferably 1 mass % or less, very preferably 0.7 mass % or less, much more preferably 0.5 mass % or less, based on the total mass of the CMP polishing liquid from the viewpoint of being excellent in stability and productivity.

(Third Additive: Cationic Polymer)

The CMP polishing liquid of the present embodiment can comprise a cationic polymer as a third additive, in addition to the first additive (4-pyrone-based compound) and the second additive (aromatic polyoxyalkylene compound). That is, as the third additive, the compounds corresponding to the first additive or the second additive are excluded. The CMP polishing liquid of the present embodiment can comprise at least one of the second additive and the third additive.

The “cationic polymer” is defined as a polymer having a cation group or a group which can be ionized to a cation group in the main chain or a side chain. Examples of the cation group include an amino group, an imino group, and a cyano group.

When the cationic polymer is used in combination with the aromatic polyoxyalkylene compound, the cationic polymer exerts the effect of further inhibiting the polishing rate of the stopper material from being excessively increased. Also, the cationic polymer can inhibit reduction in the polishing rate of the insulating material caused by the excessive covering of the insulating material in addition to the stopper material with the aromatic polyoxyalkylene compound, and the cationic polymer exerts the effect of further enhancing the polishing rate of the insulating material. Therefore, in the case where the aromatic polyoxyalkylene compound and the cationic polymer are used in combination, it is considered that the cationic polymer can interact with the aromatic polyoxyalkylene compound to thereby not only further suppress the polishing rate of the stopper material but also further enhance the polishing rate of the insulating material.

Examples of the cationic polymer include: polymers (an allylamine polymer, a diallylamine polymer, a vinylamine polymer, and an ethyleneimine polymer) obtained by polymerizing at least one monomer component selected from the group consisting of allylamine, diallylamine, vinylamine, ethyleneimine, and their derivatives; and polysaccharides such as chitosan and chitosan derivatives.

The allylamine polymer is a polymer obtained by polymerizing allylamine or a derivative thereof. Examples of the allylamine derivative include alkoxycarbonylated allylamines, methylcarbonylated allylamines, aminocarbonylated allylamines, and ureated allylamines.

The diallylamine polymer is a polymer obtained by polymerizing diallylamine or a derivative thereof. Examples of the diallylamine derivative include methyldiallylamines, a diallyldimethylammonium salt, a diallylmethylethylammonium salt, acylated diallylamines, aminocarbonylated diallylamines, alkoxycarbonylated diallylamines, aminothiocarbonylated diallylamines, and hydroxyalkylated diallylamines. Examples of the ammonium salt include ammonium chloride and ammonium alkyl sulfate (e.g., ammonium ethyl sulfate).

The vinylamine polymer is a polymer obtained by polymerizing vinylamine or a derivative thereof. Examples of the vinylamine derivative include alkylated vinylamines, amidated vinylamines, ethylene oxidized vinylamines, propylene oxidized vinylamines, alkoxylated vinylamines, carboxymethylated vinylamines, acylated vinylamines, and ureated vinylamines.

The ethyleneimine polymer is a polymer obtained by polymerizing ethyleneimine or a derivative thereof. Examples of the ethyleneimine derivative include an aminoethylated acrylic polymer, alkylated ethyleneimines, ureated ethyleneimines, and propylene oxidized ethyleneimines.

The cationic polymer may have a structure unit derived from a monomer component other than allylamine, diallylamine, vinylamine, ethyleneimine, and their derivatives. The cationic polymer may have, for example, a structure unit derived from acrylamide, dimethylacrylamide, diethylacrylamide, hydroxyethylacrylamide, acrylic acid, methyl acrylate, methacrylic acid, maleic acid, sulfur dioxide, or the like.

The cationic polymer may be a homopolymer of allylamine, diallylamine, vinylamine, or ethyleneimine (polyallylamine, polydiallylamine, polyvinylamine, or polyethyleneimine), or may be a copolymer having a structure unit derived from allylamine, diallylamine, vinylamine, ethyleneimine, or their derivative. In the copolymer, the arrangement of the structure unit is arbitrary. For example, any form such as (a) a block copolymerization form in which the same type structure units are respectively continued, (b) a random copolymerization form in which a structure unit A and a structure unit B are arranged without being ordered, or (c) an alternating copolymerization form in which a structure unit A and a structure unit B are alternately arranged can be adopted.

The copolymer is preferably a copolymer obtained by polymerizing a composition containing acrylamide as a monomer component, more preferably a copolymer obtained by polymerizing a composition containing a diallyldimethylammonium salt and acrylamide as monomer components, further preferably a diallyldimethylammonium chloride-acrylamide copolymer, from the viewpoint of further enhancing the polishing selectivity for the insulating material with respect to the stopper material.

Among the cationic polymers, from the viewpoint of further enhancing the polishing selectivity for the insulating material with respect to the stopper material and from the viewpoint of further enhancing the polishing rate of the insulating material, an amine polymer such as an allylamine polymer, a diallylamine polymer or a vinylamine polymer is preferable, and polyallylamine or diallyldimethylammonium chloride is more preferable. The cationic polymers can be used each alone or in combination of two or more for the purpose of adjusting polishing characteristics such as polishing selectivity and flatness.

The lower limit of the weight average molecular weight of the cationic polymer is preferably 100 or more, more preferably 300 or more, further preferably 500 or more, particularly preferably 1000 or more, extremely preferably 1500 or more, from the viewpoint of further enhancing the polishing selectivity for the insulating material with respect to the stopper material. The upper limit of the weight average molecular weight of the cationic polymer is preferably 1000000 or less, more preferably 600000 or less, further preferably 300000 or less, particularly preferably 200000 or less, from the viewpoint of further enhancing the polishing selectivity for the insulating material with respect to the stopper material. Herein, the weight average molecular weight of the cationic polymer can be measured by the same method as in the weight average molecular weight of the second additive.

The lower limit of the content of the cationic polymer is preferably 0.00001 mass % or more, more preferably 0.00003 mass % or more, further preferably 0.00005 mass % or more, particularly preferably 0.00006 mass % or more, extremely preferably 0.00007 mass % or more, based on the total mass of the CMP polishing liquid from the viewpoint of further enhancing the polishing selectivity and flatness. The upper limit of the content of the cationic polymer is preferably 5 mass % or less, more preferably 1 mass % or less, further preferably 0.1 mass % or less, particularly preferably 0.01 mass % or less, extremely preferably 0.005 mass % or less, very preferably 0.001 mass % or less, much more preferably 0.0005 mass % or less, further preferably 0.0003 mass % or less, particularly preferably 0.0002 mass % or less, based on the total mass of the CMP polishing liquid from the viewpoint of having further excellent polishing selectivity. It is preferable that the content of the cationic polymer is appropriately adjusted depending on the preparation method of the insulating material (e.g., type and film formation conditions) from the viewpoint of further enhancing the polishing rate of the insulating material, the polishing selectivity for the insulating material with respect to the stopper material, and flatness.

(Fourth Additive)

It is preferable that the CMP polishing liquid of the present embodiment further comprises a saturated monocarboxylic acid as a fourth additive. The CMP polishing liquid of the present embodiment can comprise at least one selected from the group consisting of the second additive, the third additive, and the fourth additive. By using the fourth additive and the first additive in combination, the insulating material having no irregularities (e.g., an insulating material of a wafer having no irregularities (blanket wafer)) can be polished at a more satisfactory polishing rate. In general, in the polishing of a wafer having irregularities, the convex regions are preferentially polished, and as the polishing proceeds, the surface to be polished is flattened. In this case, the polishing rate of the surface to be polished tends to get close to the polishing rate of a blanket wafer. Therefore, a polishing liquid excellent not only in the polishing rate of the insulating material having irregularities but in the polishing rate of the insulating material having no irregularities is preferable from the viewpoint that a satisfactory polishing rate is obtained through the whole polishing process. In addition, by using the fourth additive and the first additive in combination, a higher polishing rate of the insulating material (e.g., a semiconductor substrate) having irregularities is achieved, while the polishing rate of the insulating material (e.g., a semiconductor substrate) having no irregularities is enhanced, and in-plane uniformity which is an index for uneven polishing rates within the surface to be polished can also be enhanced.

The number of carbon atoms in the saturated monocarboxylic acid is preferably 2 to 6 from the viewpoint that the enhancement effect of the polishing rate of the insulating material (e.g., a semiconductor substrate) having no irregularities and the enhancement effect of in-plane uniformity are more satisfactorily obtained. As the saturated monocarboxylic acid, at least one compound selected from the group consisting of acetic acid, propionic acid, butyric acid, isobutyric acid, valeric acid, isovaleric acid, pivalic acid, hydroangelic acid, caproic acid, 2-methylpentanoic acid, 4-methylpentanoic acid, 2,3-dimethylbutanoic acid, 2-ethylbutanoic acid, 2,2-dimethylbutanoic acid, and 3,3-dimethylbutanoic acid is preferable. The number of carbon atoms in the saturated monocarboxylic acid is more preferably 3 or more from the viewpoint of obtaining a higher polishing rate of the insulating material. Also, from the viewpoint of being easy to use in the polishing liquid because the water solubility is satisfactory and from the viewpoint of being inexpensive and easily available, a saturated monocarboxylic acid having 2 or 3 carbon atoms is preferable, and specifically acetic acid and propionic acid are preferable. From the above, propionic acid is particularly preferable from the viewpoint of balancing among the polishing rate, water solubility, easy availability, and the like. The saturated monocarboxylic acids may be used each alone or may be used in combination of two or more.

In the case of using the saturated monocarboxylic acid as the fourth additive, the content of the saturated monocarboxylic acid is preferably 0.001 to 5 mass % based on the total mass of the CMP polishing liquid. This more efficiently produces the enhancement effect of the polishing rate of the insulating material (e.g., a semiconductor substrate) having no irregularities and the enhancement effect of in-plane uniformity. Also, the lower limit of the content of the saturated monocarboxylic acid is preferably 0.001 mass % or more, more preferably 0.005 mass % or more, further preferably 0.010 mass % or more, particularly preferably 0.020 mass % or more, based on the total mass of the CMP polishing liquid. When the content of the saturated monocarboxylic acid is 0.001 mass % or more, it is easy to obtain the effect of the saturated monocarboxylic acid to facilitate the polishing of the insulating material having no irregularities at a more satisfactory polishing rate. The upper limit of the content of the saturated monocarboxylic acid is preferably 5 mass % or less, more preferably 3 mass % or less, further preferably 2 mass % or less, particularly preferably 1 mass % or less, extremely preferably 0.5 mass % or less, very preferably 0.1 mass % or less, much more preferably 0.05 mass % or less, further preferably 0.03 mass % or less, based on the total mass of the CMP polishing liquid. When the content of the saturated monocarboxylic acid is 5 mass % or less, the aggregation of the abrasive grain is more easily suppressed and a high polishing rate and a satisfactory in-plane uniformity are more easily achieved, as compared with the case of exceeding 5 mass %.

(Water)

The water used for preparing the CMP polishing liquid is not particularly limited, but is preferably deionized water, ion-exchanged water, ultrapure water, or the like. Herein, if necessary, a polar solvent such as ethanol and acetone, or the like may be used in combination with water.

(Other Components)

The CMP polishing liquid of the present embodiment can comprise a surfactant, dextrin, or the like from the viewpoint of further enhancing the dispersion stability of the abrasive grain, the flatness of the surface to be polished, and/or the polishing rate of the surface to be polished. Examples of the surfactant include an ionic surfactant and a nonionic surfactant, and a nonionic surfactant is preferable. The surfactants may be used each alone or may be used in combination of two or more.

Examples of the nonionic surfactant include: ether-type surfactants such as polyoxypropylene polyoxyethylene alkyl ether, polyoxyethylene alkyl ether, polyoxyethylene alkylallyl ether, polyoxyethylene polyoxypropylene ether derivatives, polyoxypropylene glyceryl ether, polyethylene glycol, methoxypolyethylene glycol, and oxyethylene adducts of acetylene-based diols; ester-type surfactants such as sorbitan fatty acid ester and glycerol borate fatty acid ester; amino ether-type surfactants such as polyoxyethylene alkylamine; ether ester-type surfactants such as polyoxyethylene sorbitan fatty acid ester, polyoxyethylene glycerol borate fatty acid ester, and polyoxyethylene alkyl ester; alkanolamide-type surfactants such as fatty acid alkanolamide and polyoxyethylene fatty acid alkanolamide; oxyethylene adducts of acetylene-based diols; polyvinyl pyrrolidone; polyacrylamide; polydimethylacrylamide; and polyvinyl alcohol. These may be used each alone or may be used in combination of two or more.

The CMP polishing liquid of the present embodiment may further comprise components other than the surfactant in accordance with the desired characteristics. Examples of such a component include a pH adjuster mentioned later, a pH buffer for suppressing the variation of pH, an aminocarboxylic acid, and a cyclic monocarboxylic acid. The content of these components is preferably within a range not to excessively lower the above effects due to the CMP polishing liquid.

(pH)

The upper limit of the pH of the CMP polishing liquid is preferably less than 8.0, more preferably 7.0 or less, further preferably 6.0 or less, particularly preferably 5.0 or less. When the pH is less than 8.0, the aggregation of the abrasive grain and the like is more easily suppressed and the effect of the addition of the additives is more easily obtained, as compared with the case of 8.0 or more. The lower limit of the pH of the CMP polishing liquid is preferably 1.5 or more, more preferably 2.0 or more, further preferably 2.5 or more, particularly preferably 3.0 or more. When the pH is 1.5 or more, the absolute value of the zeta potential of the insulating material can be more easily adjusted to a large value as compared with the case of less than 1.5. Herein, the pH is defined as the pH at a liquid temperature of 25° C.

Also, by adjusting the pH of the CMP polishing liquid to within the range of 1.5 or more and less than 8.0, it is considered that the following two effects are easily obtained.

(a) Protons or hydroxy anions act on a compound included as an additive so that the chemical form of the compound is altered to thereby enhance wettability and affinity for the insulating material or the stopper material (silicon nitride and the like) on the substrate surface.

(b) Since the abrasive grain is a cerium oxide particle, the contact efficiency between the abrasive grain and the insulating material is enhanced and a high polishing rate is easily achieved. This is because in the case where the sign of the zeta potential of cerium oxide is positive, the sign of the zeta potential of the insulating material is negative and electrostatic attraction works between them.

Since the pH of the CMP polishing liquid may vary depending on the type of a compound used as an additive, a pH adjuster may be used as an additive in order to adjust the pH within the above range. Examples of the pH adjuster include, but are not particularly limited to: acids such as nitric acid, sulfuric acid, hydrochloric acid, phosphoric acid, and boric acid; and bases such as sodium hydroxide, ammonia, potassium hydroxide, and calcium hydroxide. The fourth additive (saturated monocarboxylic acid) may be used as the pH adjuster.

The pH of the CMP polishing liquid of the present embodiment can be measured with a pH meter (e.g., Model Number PHL-40 manufactured by Denki Kagaku Keiki Co., Ltd.). For example, after performing 2-point calibration of the pH meter by using a phthalate pH buffer solution (pH 4.01) and a neutral phosphate pH buffer solution (pH 6.86) as standard buffer solutions, an electrode of the pH meter is placed in the polishing liquid for 2 minutes or more, and the value after stabilization is measured. In this case, the liquid temperatures of each of the standard buffer solutions and of the polishing liquid are both set to 25° C.

<Preparation Method and Use Method of CMP Polishing Liquid>

CMP polishing liquids can be classified into (A) general type, (B) concentrated type and (C) two-liquid type and differ in preparation method and use method depending on the types. (A) general type is a polishing liquid that can be used as it is without pretreatment such as dilution at the time of polishing. (B) concentrated type is a polishing liquid in which the components have been concentrated, as compared with (A) general type, in consideration of the convenience of storage or transport. (C) two-liquid type is a polishing liquid that is used such that it is in a divided state of a liquid A containing a given component and a liquid B containing the other components at the time of storage or transport and these liquids are mixed before use.

(A) general type can be obtained by dissolving or dispersing the additives including the specific compound, the abrasive grain, and, if necessary, other components in water which is a main dispersion medium. For example, for the preparation of 1000 g of a CMP polishing liquid comprising an abrasive grain at a content of 0.5 mass % and an additive at a content of 0.1 mass % based on the total mass of the CMP polishing liquid, the amounts can be adjusted to 5 g of the abrasive grain and 1 g of the additive with respect to the total amount of the CMP polishing liquid.

(B) concentrated type is diluted immediately before use such that the contents of the components are adjusted to desired contents. After the dilution, stirring and/or dispersion treatment of the abrasive grain may be performed over an arbitrary time until liquid characteristics (pH, the particle diameter of the abrasive grain, and the like) and polishing characteristics (the polishing rate of the insulating material, selecting ratio with respect to silicon nitride, and the like) at the same levels as those of (A) general type can be reproduced. In (B) concentrated type, the volume is decreased depending on the degree of concentration, and the cost required for storage and transport can therefore be reduced.

The concentration rate is preferably 1.5-fold or more, more preferably 2-fold or more, further preferably 3-fold or more, particularly preferably 5-fold or more. When the concentration rate is 1.5-fold or more, advantages related to storage and transport can be obtained as compared with the case of less than 1.5-fold. The concentration rate is preferably 50-fold or less, more preferably 40-fold or less, further preferably 30-fold or less. When the concentration rate is 50-fold or less, the aggregation of the abrasive grain is more easily suppressed as compared with the case of exceeding 50-fold.

It is to be noted for use of (B) concentrated type that the pH varies between before and after dilution with water. In order to prepare a polishing liquid having the same pH as that of (A) general type from (B) concentrated type, the pH of the polishing liquid of (B) concentrated type can be set to a low value in advance by taking elevation in pH caused by mixing with water into consideration. For example, in the case of diluting the polishing liquid of (B) concentrated type of pH 4.0 10-fold by using water containing carbon dioxide dissolved therein (pH: approximately 5.6), the pH of the polishing liquid after the dilution is elevated to approximately 4.3.

The pH of (B) concentrated type is preferably 1.5 to 7.0 from the viewpoint of obtaining the polishing liquid of suitable pH after dilution with water. The lower limit of the pH is more preferably 2.0 or more, further preferably 2.5 or more. The upper limit of the pH is preferably 7.0 or less, more preferably 6.7 or less, further preferably 6.0 or less, particularly preferably 5.5 or less, from the viewpoint of suppressing the aggregation of the abrasive grain.

(C) two-liquid type has the advantage that the aggregation of the abrasive grain and the like can be circumvented as compared with (B) concentrated type. The components respectively contained in the liquid A and the liquid B are arbitrary. In the first embodiment, the liquid A is, for example, a slurry containing the abrasive grain, and a surfactant or the like included if necessary. In the first embodiment, the liquid B is, for example, a solution containing the first additive, and other components (fourth additive and the like) included if necessary. In the second embodiment, the liquid A is, for example, a slurry containing the abrasive grain, the first additive, and other components (fourth additive and the like) included if necessary. In the second embodiment, the liquid B is, for example, a solution containing the second additive, the third additive, and a surfactant or the like included if necessary. In this case, in order to enhance the dispersibility of the abrasive grain in the liquid A, an arbitrary acid or base may be included in the liquid A to perform pH adjustment.

The polishing liquid of (C) two-liquid type is useful for the case where polishing characteristics are reduced in a relatively short time due to the aggregation of the abrasive grain and the like in the state where the components are mixed. Herein, at least one of the liquid A and the liquid B may be concentrated type from the viewpoint of reduction in the cost required for storage and transport. In this case, at the time of using the polishing liquid, the liquid A, the liquid B and water can be mixed. The concentration rates and pHs of the liquid A and the liquid B are arbitrary as long as the liquid characteristics and polishing characteristics of the final mixture are at the same levels as those of the polishing liquid of (A) general type.

<Polishing Method>

The polishing method of the present embodiment comprises a polishing step of polishing the insulating material by using the CMP polishing liquid of the present embodiment. The polishing method of the present embodiment is, for example, a polishing method for polishing a substrate having an insulating material on the surface thereof, comprising a polishing step of polishing the insulating material by using the CMP polishing liquid of the present embodiment. For example, the polishing method of the present embodiment comprises a polishing step in which, in the state where the CMP polishing liquid of the present embodiment is supplied to between the insulating material of the substrate having an insulating material on the surface thereof and a predetermined member for polishing (polishing member, for example, a polishing pad (polishing cloth)), while the insulating material is pressed on the polishing member, at least either of the substrate and the polishing member is moved to polish the insulating material with the polishing member. In the polishing step, at least a portion of the insulating material is removed by polishing. In the polishing step, for example, by using the polishing liquid in which the respective contents of the components, the pH and the like are adjusted, the substrate having an insulating material on the surface thereof is flattened by the CMP technique.

Examples of the insulating material include inorganic insulating materials and organic insulating materials. The insulating material may be doped with an element such as phosphorus or boron. Examples of the inorganic insulating materials include silicon-based insulating materials and specifically include silicon oxide-based materials containing a silicon atom and an oxygen atom, silicon carbide-based materials containing a silicon atom and a carbon atom, and silicon nitride-based materials containing a silicon atom and a nitrogen atom. For more efficiently obtaining the effect excellent in step height elimination characteristics, a silicon oxide-based material that may have a hydroxy group (e.g., a silanol group) on the surface thereof is preferable, and silicon oxide is more preferable. Examples of the organic insulating materials include wholly aromatic low-permittivity insulating materials. As the insulating material, an inorganic insulating material is preferable, a silicon-based insulating material is more preferable, and silicon oxide is further preferable, from the viewpoint of achieving a higher polishing rate. The insulating material may be, for example, in a film form (insulating film).

According to the polishing method using the CMP polishing liquid of the second embodiment, a high stopping property of the stopper material can be obtained. Such a polishing method is suitable for polishing the insulating material having irregularities by using a stopper including a stopper material. The polishing method using the CMP polishing liquid of the second embodiment is suitable for a polishing method of polishing the insulating material and stopping the polishing at the stage where the stopper is exposed. This is because the CMP polishing liquid of the second embodiment can achieve a high polishing rate of the insulating material and a high stopping property of the stopper material. In the polishing method using the CMP polishing liquid of the second embodiment, the insulating material can be selectively polished with respect to the stopper material. The polishing rate ratio of the insulating material with respect to the stopper material (polishing rate of the insulating material/polishing rate of the stopper material) is preferably 30 or more, more preferably 50 or more, further preferably 100 or more.

Examples of the stopper material include silicon nitride and polysilicon, and polysilicon is preferable from the viewpoint of achieving a higher stopping property.

The polishing method of the present embodiment is suitable for polishing the substrate having an insulating material on the surface thereof in the production process of a device. Examples of the device include: discrete semiconductors such as diode, transistor, compound semiconductor, thermistor, varistor, and thyristor; memory elements such as DRAM (dynamic random access memory), SRAM (static random access memory), EPROM (erasable programmable read only memory), mask ROM (mask read only memory), EEPROM (electrical erasable programmable read only memory), and flash memory; logic circuit elements such as microprocessor, DSP, and ASIC; integrated circuit elements of compound semiconductor and the like, typified by MMIC (monolithic microwave integrated circuit); hybrid integrated circuit (hybrid IC); light emitting diode; and photoelectric conversion elements such as charge coupled device element.

The CMP polishing liquid of the present embodiment can achieve a high polishing rate of the insulating material without significantly depending on the state of the surface to be polished. Therefore, the polishing method using this CMP polishing liquid can be applied even to a substrate for which it is difficult to achieve a high polishing rate by means of methods using conventional CMP polishing liquids.

The polishing method of the present embodiment is particularly suitable for the flattening of the surface to be polished having irregularities (step height) on the surface. Examples of a substrate having such surface to be polished include substrates of logic semiconductor devices. In addition, the surface of the substrate may have T-shaped or lattice shaped concave regions or convex regions, and the polishing method of the present embodiment is suitable for polishing a substrate having portions in which T-shaped or lattice shaped concave regions or convex regions are arranged as viewed from above (direction opposed to the surface of the substrate). For example, the insulating material provided on the surface of a semiconductor substrate having a memory cell (e.g., a substrate of a device such as DRAM or flash memory) can be polished at a high polishing rate. These objects to be polished are the objects to be polished for which it is difficult to achieve a high polishing rate by means of methods using conventional CMP polishing liquids, and such effects therefore show that the CMP polishing liquid of the present embodiment can achieve a high polishing rate without significantly depending on the irregular shape of the surface to be polished.

Herein, the substrate to which the polishing method of the present embodiment can be applied is not limited to a substrate in which the whole surface to be polished is made of one material to be polished, and may be a substrate in which the surface to be polished is made of two or more materials to be polished.

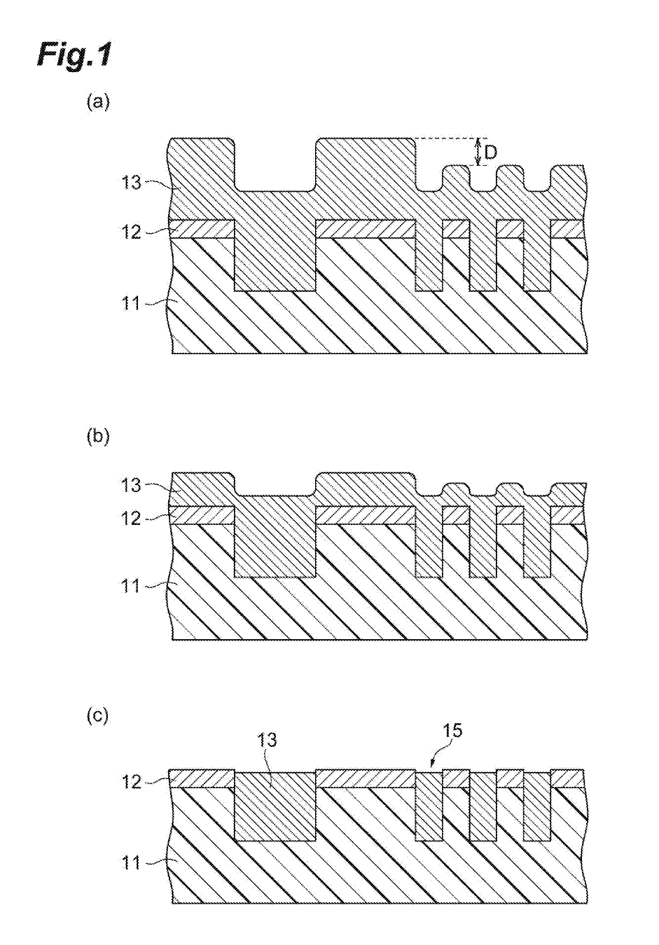

The polishing method of the present embodiment is particularly suitable for CMP in the STI formation step, the ILD formation step, or the like. With reference to FIG. 1, the process for forming a STI structure on a substrate (wafer) by the CMP using the polishing method of the present embodiment will be described. The polishing method of the present embodiment has, for example, a first polishing step (coarse polishing step) of polishing silicon oxide 13 at a high polishing rate, and a second polishing step (finishing step) of polishing the residual silicon oxide 13 at a relatively low polishing rate.

FIG. 1(a) is a cross-sectional view illustrating a substrate before polishing. FIG. 1(b) is a cross-sectional view illustrating the substrate after the first polishing step. FIG. 1(c) is a cross-sectional view illustrating the substrate after the second polishing step. As shown in FIG. 1, in the process for forming the STI structure, in order to eliminate the step height (difference of elevation of the thickness of the silicon oxide) D of the silicon oxide 13 formed on a silicon substrate 11, partially protruding unnecessary portions are preferentially removed by CMP. Herein, in order to appropriately stop the polishing at the point of time where the surface is flattened, it is preferable that a stopper (silicon nitride or polysilicon) 12 having a slow polishing rate is beforehand formed under the silicon oxide 13. By passing through the first polishing step and the second polishing step, the step height D of the silicon oxide 13 is eliminated, and therefore, an element isolation structure having an embedded portion 15 is formed.

In the polishing of the silicon oxide 13, the substrate (wafer) is disposed on the polishing pad in such a way that the surface of the silicon oxide 13 and the polishing pad are in contact with each other, and the surface of the silicon oxide 13 is polished with the polishing pad. More specifically, while the surface to be polished side of the silicon oxide 13 is pressed to the polishing pad on the polishing platen and the CMP polishing liquid is supplied between the surface to be polished and the polishing pad, both of these are relatively moved to polish the silicon oxide 13.

The CMP polishing liquid of the present embodiment can be applied to both of the first polishing step and the second polishing step. Herein, the case where the polishing step is performed as divided into two stages is described as an example, but the polishing process from the state shown in FIG. 1(a) to the state shown in FIG. 1(c) can be performed as a single stage.

As the polishing apparatus, for example, an apparatus provided with a holder for holding a substrate, a polishing platen to which a polishing pad is attached, and a means to supply a polishing liquid to the polishing pad is preferable. Examples of the polishing apparatus include the polishing apparatuses (Model Numbers: EPO-111, EPO-222, FREX200 and FREX300) manufactured by Ebara Corp., and the polishing apparatus (trade name: Mirra 3400, Reflexion Polishing Machine) manufactured by Applied Materials, Inc. As the polishing pad, for example, common unwoven cloth, foamed polyurethane, porous fluororesin or the like can be used without being particularly limited. Also, it is preferable that the polishing pad is subjected to grooving so that the polishing liquid is pooled.

The polishing conditions are not particularly limited, but the rotation speed of the polishing platen is preferably 200 min⁻¹ or less from the viewpoint of preventing the substrate from being let out, and the pressure to be applied to the substrate (processing load) is preferably 100 kPa or less from the viewpoint of suppressing the occurrence of scratches on the polished surface. It is preferable to continuously supply the polishing liquid to the polishing pad through a pump or the like during polishing. The amount of supply thereof is not limited, but it is preferable that the surface of the polishing pad is always covered with the polishing liquid.

It is preferable that, after completion of the polishing, the substrate is sufficiently washed with flowing water, and then, a spin dryer or the like is used to flick a water droplet attached to the substrate, followed by drying. By polishing in this way, the irregularities on the surface can be eliminated to obtain flat and smooth surface overall the surface of the substrate. By repeating the formation of the material to be polished and the step of polishing the material to be polished a predetermined number of times, a substrate having a desired number of layers can be produced.

The substrate obtained in this way can be used as various electronic components. Specific examples include: semiconductor elements; optical glass for a photomask, a lens, a prism, or the like; inorganic conductive materials of ITO or the like; optical integrated circuits constituted with glass and crystalline materials; optical switching elements; optical waveguides; end faces of optical fibers; optical single crystals such as scintillators; solid laser single crystals; sapphire substrates for blue laser LEDs; semiconductor single crystals of SiC, GaP, GaAs or the like; glass substrates for magnetic discs; and magnetic heads.

### EXAMPLES

Hereinafter, the present invention will be described in more detail by way of Examples, but the present invention is not limited to these Examples.

<Preparation of Cerium Oxide Particle and Evaluation of Characteristics>

Water dispersions containing cerium oxide particles 1 to 9 having the features shown in Table 1 were prepared. The content of each cerium oxide particle was adjusted to 6 mass % or more based on the total mass of the water dispersion. In Table 1, R represents an average particle diameter, S1 represents the specific surface area of a spherical virtual cerium oxide particle having the average particle diameter R, and S2 represents the specific surface area of the cerium oxide particle measured by the BET method.

The average particle diameter R was measured in the monodisperse mode of a submicron particle analyzer “N5” manufactured by Beckman Coulter, Inc. Measurement for 240 seconds was performed by using a water dispersion of the cerium oxide particle obtained by adjusting (dilution with water) intensity (signal intensity) obtained from the submicron particle analyzer “N5” manufactured by Beckman Coulter, Inc. to within the range of 1.0E+4 to 1.0E+6, and the obtained results were used as the average particle diameter R.

The specific surface area S1 was determined on the basis of the average particle diameter R. Herein, as the density of cerium oxide, 7.2×10⁶ g/m³ was adopted.

The specific surface area S2 was determined as follows: first, 100 g of the water dispersion of the cerium oxide particle was placed in a dryer and then dried at 150° C. to obtain the cerium oxide particle. Approximately 0.4 g of the obtained cerium oxide particle was placed in a measurement cell of a BET specific surface area measurement apparatus (NOVA-1200, manufactured by Yuasa Ionics Co., Ltd.) and then degassed in vacuum at 150° C. for 60 minutes. A value obtained as “Area” by measurement according to the constant volume method using nitrogen gas as an adsorption gas was obtained as a BET specific surface area. The measurement was performed twice, and an average value thereof was determined as the specific surface area S2.

TABLE 1

| | R [nm] | S2 [m²/g] | S1 [m²/g] | S2/S1 |
|---|---|---|---|---|
| Cerium oxide particle 1 | 144.1 | 12.6 | 5.8 | 2.17 |
| Cerium oxide particle 2 | 135.4 | 14.6 | 6.1 | 2.39 |
| Cerium oxide particle 3 | 133.3 | 17.8 | 6.2 | 2.87 |
| Cerium oxide particle 4 | 103.4 | 23.1 | 8.0 | 2.89 |
| Cerium oxide particle 5 | 81.9 | 30.7 | 10.2 | 3.01 |
| Cerium oxide particle 6 | 32.1 | 92.6 | 25.9 | 3.58 |
| Cerium oxide particle 7 | 123.1 | 22.4 | 6.8 | 3.29 |
| Cerium oxide particle 8 | 134.5 | 20.2 | 6.2 | 3.26 |
| Cerium oxide particle 9 | 224.0 | 15.8 | 3.7 | 4.27 |

### Experiment A

### [Preparation of CMP Polishing Liquid]

The components shown in Tables 2 and 3 were included in containers and then mixed to prepare CMP polishing liquids. The unit of amount of component in Tables 2 and 3 is “mass %”. The pHs of the CMP polishing liquids were adjusted to the values shown in Tables 2 and 3 by using nitric acid or ammonia water. The pHs were measured by using Model Number PHL-40 manufactured by Denki Kagaku Keiki Co., Ltd. The cerium oxide particles 1 to 9 shown in Tables 2 and 3 are the cerium oxide particles shown in Table 1.

[Measurement of Zeta Potential]

The zeta potentials of the cerium oxide particles in the CMP polishing liquids were measured by using Delsa Nano C (manufactured by Beckman Coulter, Inc.). All of the zeta potentials were 15 mV or more and 100 mV or less.

[Polishing of Insulating Film]

As test wafers for CMP evaluation, a blanket wafer having no irregularities (no pattern was formed) and a patterned wafer (wafer with a pattern) having irregularities (pattern was formed) were used. As the blanket wafer, a wafer having a silicon oxide film of 1000 nm in thickness on a silicon (Si) substrate (diameter: 300 mm) was used. As the patterned wafer, trade name “Patterned Wafer 764” (diameter: 300 mm, stopper: silicon nitride film) manufactured by SEMATECH was used.

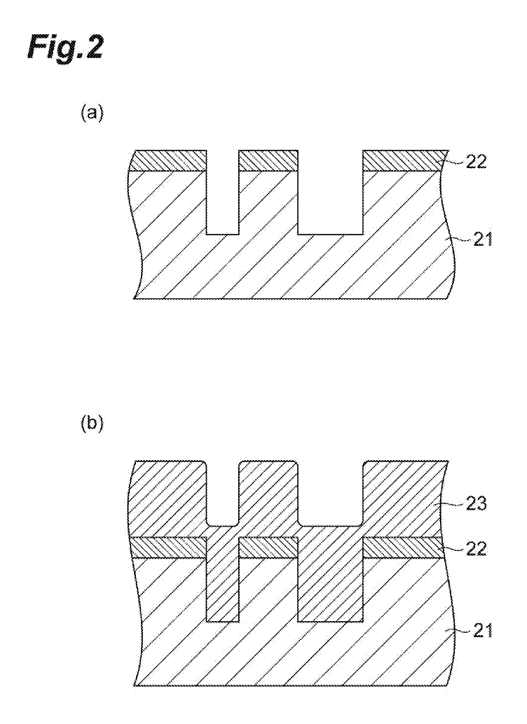

The patterned wafer will be further described with reference to FIG. 2. The patterned wafer has a wafer 21, a stopper (silicon nitride film) 22, and a silicon oxide film 23. FIG. 2(a) is a schematic cross-sectional view in which a portion of the wafer 21 and the stopper 22 is enlarged. A plurality of grooves are formed on the surface of the wafer 21, and the stopper 22 of 150 nm in thickness is formed on the surface of the convex regions of the wafer 21. The depth of the grooves (step height from the surface of the convex region to the bottom of the concave region) is 500 nm. Hereinafter, the convex regions are referred to as active regions, and the concave regions are referred to as trench regions. Herein, in the wafer 21, 100 μm/100 μm of trench regions/active regions are formed.

FIG. 2(b) is a schematic cross-sectional view in which a portion of the patterned wafer is enlarged. In the patterned wafer, the silicon oxide film 23 is formed on the active regions and the trench regions by the plasma TEOS method such that the thickness of the silicon oxide film 23 from the surface of the active regions is 600 nm.

In the polishing of the test wafers for CMP evaluation, a polishing apparatus (Reflexion manufactured by Applied Materials, Inc.) was used. Each test wafer for CMP evaluation was placed in a holder to which an adsorption pad for substrate installation was attached. A polishing pad made of porous urethane resin (manufactured by Rohm and Haas Japan K.K., Model Number IC1010) was attached to the polishing platen of 600 mm in diameter in the polishing apparatus. The holder was placed on the polishing platen in such a way that the surface provided with the insulating film (silicon oxide film) as a film to be polished faced downward, and the processing load was set to 140 gf/cm² (13.8 kPa).

While each of the above CMP polishing liquids was added dropwise at a rate of 250 mL/min to the polishing platen, the polishing platen and the test wafer for CMP evaluation were rotated at 93 min⁻¹ and 87 min⁻¹, respectively, to polish each of the two test wafers for CMP evaluation for 60 seconds. The wafers after the polishing were well washed with pure water by using a PVA brush (polyvinyl alcohol brush) and then dried.

Evaluation was conducted for the following items. The evaluation results are shown in Tables 2 and 3.

### (Polishing Rate of Silicon Oxide in Blanket Wafer)

The film thickness of the silicon oxide film was measured before and after polishing by using a light interference-type film thickness apparatus (manufactured by SCREEN Holdings Co., Ltd., trade name: RE-3000), and the polishing rate of silicon oxide in the blanket wafer was calculated from the average amount of change in film thickness. Herein, the unit of the polishing rate is nm/min.

### (Polishing Rate of Silicon Oxide in Patterned Wafer)

The film thickness of 100 μm/100 μm of active regions (convex regions) was measured before and after polishing by using a light interference-type film thickness apparatus (manufactured by SCREEN Holdings Co., Ltd., trade name: RE-3000), and the polishing rate of silicon oxide in the patterned wafer was calculated from the average amount of change in film thickness. Herein, the unit of the polishing rate is nm/min.

### (Polishing Rate Ratio)

The ratio of the polishing rate of silicon oxide in the patterned wafer with respect to the polishing rate of silicon oxide in the blanket wafer (patterned wafer/blanket wafer) was calculated.

TABLE 2

| | | | Example | | | | | | |
|---|---|---|---|---|---|---|---|---|---|
| | | | A1 | A2 | A3 | A4 | A5 | A6 | A7 |
| Amount of | Polishing | Cerium oxide particle 1 | 0.25 | — | — | — | — | — | — |
| component | particle | Cerium oxide particle 2 | — | 0.25 | — | — | — | — | — |
| | | Cerium oxide particle 3 | — | — | 0.25 | — | — | 0.05 | 1.00 |
| | | Cerium oxide particle 4 | — | — | — | 0.25 | — | — | — |
| | | Cerium oxide particle 5 | — | — | — | — | 0.25 | — | — |
| | | Cerium oxide particle 6 | — | — | — | — | — | — | — |
| | | Cerium oxide particle 7 | — | — | — | — | — | — | — |
| | | Cerium oxide particle 8 | — | — | — | — | — | — | — |
| | | Cerium oxide particle 9 | — | — | — | — | — | — | — |
| | Maltol | | 0.02 | 0.02 | 0.02 | 0.02 | 0.02 | 0.02 | 0.02 |
| | Propionic acid | | 0.02 | 0.02 | 0.02 | 0.02 | 0.02 | 0.02 | 0.02 |
| | Water | | 99.71 | 99.71 | 99.71 | 99.71 | 99.71 | 99.91 | 98.96 |
| pH | | | 3.0 | 3.0 | 3.0 | 3.0 | 3.0 | 3.0 | 3.0 |
| Polishing rate | | Blanket wafer | 230 | 208 | 188 | 132 | 88 | 142 | 230 |
| [nm/min] | | Patterned wafer | 478 | 461 | 417 | 289 | 198 | 312 | 518 |
| Polishing rate ratio | | Patterned wafer/blanket | 2.08 | 2.22 | 2.22 | 2.19 | 2.25 | 2.20 | 2.25 |
| | | wafer | | | | | | | |
| | | | Example | | | | | | |
| | | | A8 | A9 | A10 | A11 | A12 | A13 | A14 |
| Amount of | Polishing | Cerium oxide particle 1 | — | — | — | — | — | — | — |
| component | particle | Cerium oxide particle 2 | — | — | — | — | — | — | — |
| | | Cerium oxide particle 3 | 0.25 | 0.25 | 0.25 | 0.25 | 0.25 | 0.25 | 0.25 |
| | | Cerium oxide particle 4 | — | — | — | — | — | — | — |
| | | Cerium oxide particle 5 | — | — | — | — | — | — | — |
| | | Cerium oxide particle 6 | — | — | — | — | — | — | — |
| | | Cerium oxide particle 7 | — | — | — | — | — | — | — |
| | | Cerium oxide particle 8 | — | — | — | — | — | — | — |
| | | Cerium oxide particle 9 | — | — | — | — | — | — | — |

| | | | | | | | |
|---|---|---|---|---|---|---|---|
| Maltol | 0.01 | 0.10 | 0.02 | 0.02 | 0.02 | 0.02 | 0.02 |
| Propionic acid | 0.02 | 0.02 | 0.02 | 0.02 | 0.02 | 0.02 | — |
| Water | 99.72 | 99.63 | 99.71 | 99.71 | 99.71 | 99.71 | 99.73 |

| pH | | 3.0 | 3.0 | 2.0 | 4.0 | 5.0 | 6.0 | 4.0 |
|---|---|---|---|---|---|---|---|---|
| Polishing rate | Blanket wafer | 197 | 91 | 185 | 178 | 170 | 161 | 169 |
| [nm/min] | Patterned wafer | 395 | 445 | 412 | 400 | 391 | 372 | 370 |
| Polishing rate ratio | Patterned wafer/blanket | 2.01 | 4.89 | 2.23 | 2.25 | 2.30 | 2.31 | 2.19 |
| | wafer | | | | | | | |

TABLE 3

| | | | Comparative Example | | | | |
|---|---|---|---|---|---|---|---|
| | | | A1 | A2 | A3 | A4 | A5 |
| Amount of | Polishing | Cerium oxide particle 1 | — | — | — | — | — |
| component | particle | Cerium oxide particle 2 | — | — | — | — | — |
| | | Cerium oxide particle 3 | 0.25 | — | — | — | — |
| | | Cerium oxide particle 4 | — | — | — | — | — |
| | | Cerium oxide particle 5 | — | — | — | — | — |
| | | Cerium oxide particle 6 | — | 0.25 | — | — | — |
| | | Cerium oxide particle 7 | — | — | 0.25 | — | — |
| | | Cerium oxide particle 8 | — | — | — | 0.25 | — |
| | | Cerium oxide particle 9 | — | — | — | — | 0.25 |

| | | | | | |
|---|---|---|---|---|---|
| Maltol | — | 0.02 | 0.02 | 0.02 | 0.02 |
| Propionic acid | — | 0.02 | 0.02 | 0.02 | 0.02 |
| Water | 99.75 | 99.71 | 99.71 | 99.71 | 99.71 |

| pH | | 3.0 | 3.0 | 3.0 | 3.0 | 3.0 |
|---|---|---|---|---|---|---|
| Polishing rate | Blanket wafer | 336 | 15 | 450 | 460 | 312 |
| [nm/min] | Patterned wafer | 75 | 15 | 385 | 388 | 276 |
| Polishing rate ratio | Patterned wafer/blanket | 0.22 | 1.00 | 0.86 | 0.84 | 0.88 |
| | wafer | | | | | |

In Examples A1 to A14 using the CMP polishing liquids comprising the cerium oxide particles 1 to 5 and the 4-pyrone-based compound, the polishing rate of silicon oxide in the blanket wafer and the polishing rate of silicon oxide in the patterned wafer were sufficiently high. Furthermore, the polishing rate ratio of silicon oxide was a sufficiently large value of 1.00 or more. From these results, it was confirmed that Examples A1 to A14 are excellent in step height elimination characteristics.

In Comparative Example A1 using the CMP polishing liquid not comprising the 4-pyrone-based compound, the polishing rate of silicon oxide in the patterned wafer was a low polishing rate of 100 nm/min or less, and the polishing rate ratio of silicon oxide was less than 1.00.

In Comparative Example A2 using the CMP polishing liquid comprising the cerium oxide particle 6, the polishing rate of silicon oxide in the blanket wafer was a polishing rate of 50 nm/min or less, and the polishing rate of silicon oxide in the patterned wafer was a polishing rate of 100 nm/min or less.

In Comparative Examples A3 to A5 using the CMP polishing liquids comprising the cerium oxide particles 7 to 9, the polishing rate ratio of silicon oxide was less than 1.00.

Also, as a result of polishing the same blanket wafer and patterned wafer as above by using a CMP polishing liquid A having composition (content of water: 99.46 mass %) containing 0.25 mass % of Dextrin PO-10 (manufactured by Mitsubishi Shoji Foodtech Co., Ltd.) in addition to the composition of Example A12, the polishing rate of silicon oxide in the blanket wafer and the polishing rate of silicon oxide in the patterned wafer were not different from those of Example A12. On the other hand, a blanket wafer of polysilicon was prepared, and then, the blanket wafer of polysilicon was polished by using each of the CMP polishing liquid of Example A12 and the CMP polishing liquid A. As a result, as the polishing rate of polysilicon in the blanket wafer, 40 nm/min was obtained in the CMP polishing liquid of Example A12, whereas 120 nm/min was obtained in the CMP polishing liquid A. The 3-fold polishing rate was obtained by using the CMP polishing liquid A, and it was therefore confirmed that dextrin has an effect of enhancing the polishing rate of polysilicon.

### Experiment B

### Preparation of CMP Polishing Liquid

### Example B1

A slurry (first liquid) containing 5.0 mass % of the cerium oxide particle 1, 0.34 mass % of 3-hydroxy-2-methyl-4-pyrone, and 0.45 mass % of propionic acid was prepared. The respective contents of the components were adjusted by using deionized water. The pH of the slurry was 3.2. The pH was measured by using Model Number PHL-40 manufactured by Denki Kagaku Keiki Co., Ltd.

An additive liquid (second liquid) containing 5 mass % of polyoxyethylene styrenated-phenyl ether and 0.0015 mass % of a diallyldimethylammonium chloride/acrylamide copolymer was prepared. The respective contents of the components were adjusted by using deionized water. The pH of the additive liquid was adjusted by using an aqueous ammonia solution. The pH of the additive liquid was 10.2. The pH was measured by using Model Number PHL-40 manufactured by Denki Kagaku Keiki Co., Ltd.

The slurry, the additive liquid and deionized water were mixed at a mass ratio of 1:1:18 to prepare a polishing liquid. Based on the total mass of the polishing liquid, the content of the cerium oxide particle 1 was 0.25 mass %, the content of the 3-hydroxy-2-methyl-4-pyrone was 0.017 mass %, the content of the polyoxyethylene styrenated-phenyl ether was 0.25 mass %, the content of the diallyldimethylammonium chloride/acrylamide copolymer was 0.000075 mass %, and the content of the propionic acid was 0.023 mass %. The pH of the polishing liquid was 3.5. The pH was measured by using Model Number PHL-40 manufactured by Denki Kagaku Keiki Co., Ltd.

### Examples B2 to B20 and Comparative Examples B1 to B4

Slurries and additive liquids were prepared in the same way as in Example B1 by using the cerium oxide particles shown in Tables 1 and 4 and the additives shown in Table 4, and then, polishing liquids comprising the components shown in Table 4 were prepared. Based on the total mass of the polishing liquid, the content of the cerium oxide particle was 0.25 mass %, and the content of the 3-hydroxy-2-methyl-4-pyrone or the 5-hydroxy-2-(hydroxymethyl)-4-pyrone was 0.017 mass %. Ammonia water was used as a pH adjuster. The pH was measured by using Model Number PHL-40 manufactured by Denki Kagaku Keiki Co., Ltd. In Table 4, the symbol “-” means that the additive of interest was not used.

Herein, the details of each additive in Table 4 are as described below.

A-1: 3-Hydroxy-2-methyl-4-pyrone

A-2: 5-Hydroxy-2-(hydroxymethyl)-4-pyrone

B-1: Polyoxyethylene styrenated-phenyl ether (manufactured by Kao Corp., trade name: Emulgen A-500, weight average molecular weight: 4500 to 5000)

B-2: Polyoxyethylene alkylphenyl ether (manufactured by Dai-ichi Kogyo Seiyaku Co., Ltd., trade name: Emulsit, weight average molecular weight: 3000 to 3500)

b-1: Polyethylene glycol (manufactured by Lion Corp., trade name: PEG600, weight average molecular weight: 600)

C-1: Diallyldimethylammonium chloride/acrylamide copolymer (manufactured by Nittobo Medical Co., Ltd., trade name: PAS-J-81, weight average molecular weight: 200000)

C-2: Polyallylamine (manufactured by Nittobo Medical Co., Ltd., trade name: PAA-01, weight average molecular weight: 1600)

C-3: Diallyldimethylammonium chloride polymer (manufactured by Nittobo Medical Co., Ltd., trade name: PAS-H-10L, weight average molecular weight: 200000)

D-1: Propionic acid

[Measurement of Zeta Potential]

The zeta potentials of the cerium oxide particles in the CMP polishing liquids were measured by using Delsa Nano C (manufactured by Beckman Coulter, Inc.). The measurement results are shown in Table 4.

TABLE 4

| | Abrasive grain | | | | | | | | | | |
|---|---|---|---|---|---|---|---|---|---|---|---|
| | | Zeta | First | Second additive | | Third additive | | Fourth additive | | | |
| | | potential | additive | | Content | | Content | | Content | pH | |
| | Type | [mV] | Type | Type | [mass %] | Type | [mass %] | Type | [mass %] | adjustment | pH |
| Example B1 | Cerium oxide particle 1 | 60 | A-1 | B-1 | 0.25 | C-1 | 0.000075 | D-1 | 0.023 | Absent | 3.5 |
| Example B2 | Cerium oxide particle 1 | 45 | A-1 | B-1 | 0.25 | C-1 | 0.000075 | D-1 | 0.023 | Present | 4.5 |
| Example B3 | Cerium oxide particle 1 | 30 | A-1 | B-1 | 0.25 | C-1 | 0.000075 | D-1 | 0.023 | Present | 5.5 |
| Example B4 | Cerium oxide particle 1 | 55 | A-1 | B-1 | 0.50 | C-1 | 0.000075 | D-1 | 0.023 | Absent | 3.5 |
| Example B5 | Cerium oxide particle 1 | 65 | A-1 | B-1 | 0.05 | C-1 | 0.000075 | D-1 | 0.023 | Absent | 3.5 |
| Example B6 | Cerium oxide particle 1 | 65 | A-1 | B-1 | 0.25 | C-1 | 0.000038 | D-1 | 0.023 | Absent | 3.5 |
| Example B7 | Cerium oxide particle 1 | 50 | A-1 | B-1 | 0.25 | C-1 | 0.000150 | D-1 | 0.023 | Absent | 3.5 |
| Example B8 | Cerium oxide particle 1 | 60 | A-1 | B-2 | 0.25 | C-1 | 0.000075 | D-1 | 0.023 | Absent | 3.5 |
| Example B9 | Cerium oxide particle 1 | 60 | A-1 | B-1 | 0.25 | C-2 | 0.000075 | D-1 | 0.023 | Absent | 3.5 |
| Example B10 | Cerium oxide particle 1 | 60 | A-1 | B-1 | 0.25 | C-3 | 0.000075 | D-1 | 0.023 | Absent | 3.5 |
| Example B11 | Cerium oxide particle 1 | 60 | A-1 | B-1 | 0.25 | C-1 | 0.000075 | — | — | Absent | 5.0 |
| Example B12 | Cerium oxide particle 1 | 60 | A-2 | B-1 | 0.25 | C-1 | 0.000075 | D-1 | 0.023 | Absent | 3.5 |
| Example B13 | Cerium oxide particle 2 | 30 | A-1 | B-1 | 0.25 | C-1 | 0.000075 | D-1 | 0.023 | Present | 5.5 |
| Example B14 | Cerium oxide particle 3 | 30 | A-1 | B-1 | 0.25 | C-1 | 0.000075 | D-1 | 0.023 | Present | 5.5 |
| Example B15 | Cerium oxide particle 4 | 30 | A-1 | B-1 | 0.25 | C-1 | 0.000075 | D-1 | 0.023 | Present | 5.5 |
| Example B16 | Cerium oxide particle 5 | 30 | A-1 | B-1 | 0.25 | C-1 | 0.000075 | D-1 | 0.023 | Present | 5.5 |
| Example B17 | Cerium oxide particle 1 | 65 | A-1 | B-1 | 0.25 | — | — | D-1 | 0.023 | Absent | 3.5 |
| Example B18 | Cerium oxide particle 1 | 65 | A-1 | — | — | C-1 | 0.000075 | D-1 | 0.023 | Absent | 3.5 |
| Example B19 | Cerium oxide particle 1 | 70 | A-1 | — | — | — | — | D-1 | 0.023 | Absent | 3.3 |
| Example B20 | Cerium oxide particle 1 | 60 | A-1 | b-1 | 0.25 | C-1 | 0.000075 | D-1 | 0.023 | Absent | 3.5 |
| Comparative Example B1 | Cerium oxide particle 6 | 30 | A-1 | B-1 | 0.25 | C-1 | 0.000075 | D-1 | 0.023 | Present | 5.5 |
| Comparative Example B2 | Cerium oxide particle 7 | 30 | A-1 | B-1 | 0.25 | C-1 | 0.000075 | D-1 | 0.023 | Present | 5.5 |
| Comparative Example B3 | Cerium oxide particle 8 | 30 | A-1 | B-1 | 0.25 | C-1 | 0.000075 | D-1 | 0.023 | Present | 5.5 |
| Comparative Example B4 | Cerium oxide particle 9 | 30 | A-1 | B-1 | 0.25 | C-1 | 0.000075 | D-1 | 0.023 | Present | 5.5 |

[CMP Evaluation]

Each of the above CMP polishing liquids was used to polish a substrate to be polished under the following polishing conditions.

(CMP Polishing Conditions)
Polishing apparatus: Reflexion (manufactured by Applied Materials, Inc.)
Flow rate of CMP polishing liquid: 250 mL/min
Substrate to be polished: “blanket wafer” and “patterned wafer” described below
Polishing pad: foamed polyurethane resin having closed pores (Model Number IC1010 produced by Rohm and Haas Japan K.K.)
Polishing pressure: 2.0 psi
Rotation speed of substrate and polishing platen: 100 min⁻¹ (rpm)
Polishing time: blanket wafer was polished for 30 seconds (0.5 min), and the patterned wafer was polished for 60 seconds (1.0 min).

(Blanket wafer)

As the blanket wafer having no irregularities, a wafer having a silicon oxide film of 1 μm (1000 nm) in thickness formed by the plasma CVD method on a silicon substrate, and a wafer having a polysilicon film of 0.2 μm (200 nm) in thickness formed by the CVD method on a silicon substrate were used.

For the blanket wafer polished under the above CMP polishing conditions, the polishing rate of each of the films to be polished (silicon oxide film and polysilicon film) was determined by the following expression. Herein, the difference in thickness of each of the films to be polished, between before and after polishing, was determined using a light interference-type film thickness apparatus (trade name: F80 manufactured by Filmetrics Japan Inc.). The measurement results are shown in Table 5.

(Polishing rate)=(Difference in film thickness (nm) of each of the films to be polished between before and after polishing)/(Polishing time (min))

(Patterned Wafer)

As the patterned wafer having irregularities, trade name “Patterned Wafer 764” (diameter: 300 mm, stopper: polysilicon film) manufactured by SEMATECH was used. This patterned wafer will be described with reference to FIG. 2. The patterned wafer has a wafer 21, a stopper (polysilicon film) 22, and a silicon oxide film 23. FIG. 2(a) is a schematic cross-sectional view in which a portion of the wafer 21 and the stopper 22 is enlarged. A plurality of grooves are formed on the surface of the wafer 21, and the stopper 22 of 150 nm in thickness is formed on the surface of the convex regions of the wafer 21. The depth of the grooves (step height from the surface of the convex region to the bottom of the concave region) is 500 nm. Hereinafter, the convex regions are referred to as active regions, and the concave regions are referred to as trench regions. Herein, in the wafer 21, 100 μm/100 μm of trench regions/active regions are formed.

FIG. 2(b) is a schematic cross-sectional view in which a portion of the patterned wafer is enlarged. In the patterned wafer, the silicon oxide film 23 is formed on the active regions and the trench regions by the plasma TEOS method such that the thickness of the silicon oxide film 23 from the surface of the active regions is 600 nm.

The film thickness was measured before and after polishing of 100 μm/100 μm of active regions (convex regions), and the polishing rate of silicon oxide in the patterned wafer was calculated from the average amount of change in film thickness. Herein, the unit of the polishing rate is nm/min. The measurement results are shown in Table 5.

(Polishing Selecting Ratio)

On the basis of the measurement results about the blanket wafer, the polishing selecting ratio of silicon oxide with respect to polysilicon (polishing rate ratio R1/R2=polishing rate R1 of silicon oxide/polishing rate R2 of polysilicon) was calculated. Also, the polishing rate ratio (patterned wafer/blanket wafer) R3/R1 of the polishing rate R3 of silicon oxide in the patterned wafer with respect to the polishing rate R1 of silicon oxide in the blanket wafer was calculated. The results are shown in Table 5.

TABLE 5

| | Polishing rate (nm/min) | | | Polishing selecting ratio | |
|---|---|---|---|---|---|
| | Blanket wafer | | Patterned wafer | Silicon oxide/ | Patterned wafer/ |
| | Silicon oxide | Polysilicon | Silicon oxide | Polysilicon | blanket wafer |
| | R1 | R2 | R3 | R1/R2 | R3/R1 |
| Example B1 | 205 | 2.0 | 420 | 103 | 2.0 |
| Example B2 | 203 | 1.8 | 410 | 113 | 2.0 |
| Example B3 | 200 | 1.3 | 405 | 154 | 2.0 |
| Example B4 | 180 | 1.9 | 380 | 95 | 2.1 |
| Example B5 | 210 | 3.5 | 420 | 60 | 2.0 |
| Example B6 | 212 | 2.5 | 425 | 85 | 2.0 |
| Example B7 | 150 | 1.3 | 315 | 115 | 2.1 |
| Example B8 | 210 | 1.9 | 425 | 111 | 2.0 |
| Example B9 | 220 | 2.3 | 441 | 96 | 2.0 |
| Example B10 | 195 | 2.5 | 435 | 78 | 2.2 |
| Example B11 | 175 | 1.3 | 362 | 135 | 2.1 |
| Example B12 | 140 | 1.8 | 289 | 78 | 2.1 |
| Example B13 | 180 | 3.0 | 370 | 60 | 2.1 |
| Example B14 | 120 | 1.9 | 260 | 63 | 2.2 |
| Example B15 | 90 | 1.5 | 205 | 60 | 2.3 |
| Example B16 | 70 | 1.0 | 152 | 70 | 2.2 |
| Example B17 | 205 | 12.0 | 420 | 17 | 2.0 |
| Example B18 | 204 | 12.0 | 415 | 17 | 2.0 |
| Example B19 | 215 | 60.0 | 440 | 4 | 2.0 |
| Example B20 | 203 | 59.0 | 410 | 3 | 2.0 |
| Comparative | 10 | 10.0 | 18 | 1 | 1.8 |
| Example B1 | | | | | |
| Comparative | 380 | 4.0 | 330 | 95 | 0.9 |
| Example B2 | | | | | |
| Comparative | 420 | 4.2 | 380 | 100 | 0.9 |
| Example B3 | | | | | |
| Comparative | 250 | 2.0 | 150 | 125 | 0.6 |
| Example B4 | | | | | |

In Examples B1 to B20, the polishing rate of silicon oxide in the blanket wafer was sufficiently high while the polishing rate ratio of the polishing rate of silicon oxide in the patterned wafer with respect to the polishing rate of silicon oxide in the blanket wafer was a sufficiently large value of 2.0 or more, and it was therefore confirmed that the step height elimination characteristics are excellent. Also, in Examples B1 to B16, the polishing selecting ratio of silicon oxide with respect to polysilicon was 60 or more, and it was therefore confirmed that a high stopping property of the stopper material was achieved. On the other hand, in Comparative Examples, the polishing rate ratio of the polishing rate of silicon oxide in the patterned wafer with respect to the polishing rate of silicon oxide in the blanket wafer was less than 2.0, and it was therefore confirmed that polishing characteristics were poorer as compared with Examples.

The present inventors described herein the best mode for carrying out the invention. Preferable modifications similar thereto may become obvious when those skilled in the art read the above description. The present inventors are fully aware of the execution of the present invention in a different mode and the execution of an invention of a similar mode to which the essence of the present invention was applied. Furthermore, in the present invention, all modifications of the contents described in claims and arbitrary various combinations of the factors can be utilized as the principles thereof. All possible arbitrary combinations thereof are incorporated in the present invention unless otherwise specified herein or unless clearly denied by the context.

### INDUSTRIAL APPLICABILITY

According to the present invention, a CMP polishing liquid capable of obtaining excellent step height elimination characteristics for an insulating material having irregularities is provided. Also, according to the present invention, a polishing method using the CMP polishing liquid is provided.

### REFERENCE SIGNS LIST

11 . . . silicon substrate, 12 . . . stopper, 13 . . . silicon oxide, 15 . . . embedded portion, 21 . . . wafer, 22 . . . stopper, 23 . . . silicon oxide film, and D . . . step height.

1. A CMP polishing liquid for polishing an insulating material, comprising:
a cerium oxide particle satisfying conditions (A) and (B) below,
a 4-pyrone-based compound represented by general formula (1) below, and
water,
condition (A): an average particle diameter R of the cerium oxide particle is 50 nm or more and 300 nm or less, and
condition (B): when the cerium oxide particle is defined as a spherical particle having the average particle diameter R, sphericity S2/S1 provided by a specific surface area S1 of the spherical particle and a specific surface area S2 of the cerium oxide particle measured by BET method is 3.15 or less. 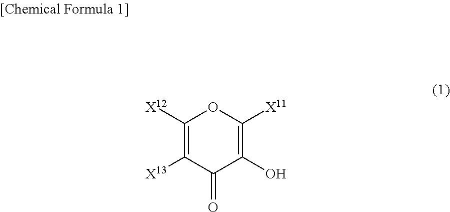
[In formula, X¹¹, X¹² and X¹³ are each independently a hydrogen atom or a monovalent substituent.]

2. A CMP polishing liquid for polishing an insulating material, comprising:
a cerium oxide particle satisfying conditions (A) and (B) below,
a 4-pyrone-based compound represented by general formula (1) below,
a polymer compound having an aromatic ring and a polyoxyalkylene chain,
a cationic polymer, and
water;
condition (A): an average particle diameter R of the cerium oxide particle is 50 nm or more and 300 nm or less, and
condition (B): when the cerium oxide particle is defined as a spherical particle having the average particle diameter R, sphericity S2/S1 provided by a specific surface area S1 of the spherical particle and a specific surface area S2 of the cerium oxide particle measured by BET method is 3.15 or less. 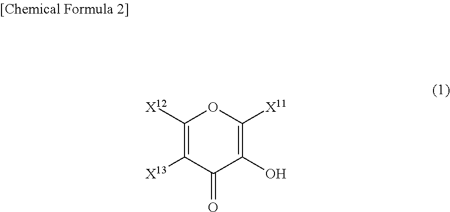
[In formula, X¹¹, X¹² and X¹³ are each independently a hydrogen atom or a monovalent substituent.]

3. The CMP polishing liquid according to claim 1, wherein a pH is less than 8.0.

4. The CMP polishing liquid according to claim 1, wherein a zeta potential of the cerium oxide particle in the CMP polishing liquid is positive.

5. The CMP polishing liquid according to claim 1, wherein the 4-pyrone-based compound is at least one selected from the group consisting of 3-hydroxy-2-methyl-4-pyrone, 5-hydroxy-2-(hydroxymethyl)-4-pyrone, and 2-ethyl-3-hydroxy-4-pyrone.

6. The CMP polishing liquid according to claim 1, further comprising a saturated monocarboxylic acid having 2 to 6 carbon atoms.

7. The CMP polishing liquid according to claim 6, wherein the saturated monocarboxylic acid is at least one selected from the group consisting of acetic acid, propionic acid, butyric acid, isobutyric acid, valeric acid, isovaleric acid, pivalic acid, hydroangelic acid, caproic acid, 2-methylpentanoic acid, 4-methylpentanoic acid, 2,3-dimethylbutanoic acid, 2-ethylbutanoic acid, 2-dimethylbutanoic acid, and 3,3-dimethylbutanoic acid.

8. The CMP polishing liquid according to claim 1, further comprising a pH adjuster.

9. A polishing method for polishing a substrate having an insulating material on the surface thereof,
the polishing method comprising a step of polishing the insulating material by using the CMP polishing liquid according to claim 1.

10. The polishing method according to claim 9, wherein the surface of the substrate has T-shaped or lattice shaped concave regions or convex regions.

11. The polishing method according to claim 9, wherein the substrate is a semiconductor substrate having a memory cell.

12. The CMP polishing liquid according to claim 2, wherein a pH is less than 8.0.

13. The CMP polishing liquid according to claim 2, wherein a zeta potential of the cerium oxide particle in the CMP polishing liquid is positive.

14. The CMP polishing liquid according to claim 2, wherein the 4-pyrone-based compound is at least one selected from the group consisting of 3-hydroxy-2-methyl-4-pyrone, 5-hydroxy-2-(hydroxymethyl)-4-pyrone, and 2-ethyl-3-hydroxy-4-pyrone.

15. The CMP polishing liquid according to claim 2, further comprising a saturated monocarboxylic acid having 2 to 6 carbon atoms.

16. The CMP polishing liquid according to claim 15, wherein the saturated monocarboxylic acid is at least one selected from the group consisting of acetic acid, propionic acid, butyric acid, isobutyric acid, valeric acid, isovaleric acid, pivalic acid, hydroangelic acid, caproic acid, 2-methylpentanoic acid, 4-methylpentanoic acid, 2,3-dimethylbutanoic acid, 2-ethylbutanoic acid, 2,2-dimethylbutanoic acid, and 3,3-dimethylbutanoic acid.

17. The CMP polishing liquid according to claim 2, further comprising a pH adjuster.

18. A polishing method for polishing a substrate having an insulating material on the surface thereof,
the polishing method comprising a step of polishing the insulating material by using the CMP polishing liquid according to claim 2.

19. The polishing method according to claim 18, wherein the surface of the substrate has T-shaped or lattice shaped concave regions or convex regions.

20. The polishing method according to claim 18, wherein the substrate is a semiconductor substrate having a memory cell.
